(19) United States
(12) Patent Application Publication
(10) Pub. No.: US 2026/0331163 A1
(43) Pub. Date: Oct. 22, 2026

(54) MEMORY DEVICE INCLUDING A BITLINE SENSE AMPLIFIER

(71) Applicant: Samsung Electronics Co., Ltd., Suwon-si (KR)

(72) Inventors: Seongsoo PARK, Suwon-si (KR); Jongcheol KIM, Suwon-si (KR); Inseok BAEK, Suwon-si (KR); Dongsu LEE, Suwon-si (KR)

(21) Appl. No.: 19/392,833

(22) Filed: Nov. 18, 2025

(30) Foreign Application Priority Data
Apr. 22, 2025 (KR) 10-2025-0052471

(51) Int. Cl. G11C 11/4091; G11C 7/06; G11C 11/4094

(52) U.S. Cl. CPC G11C 11/4091; G11C 7/065; G11C 11/4094

(57) ABSTRACT

A bitline sense amplifier of a memory device for sensing a voltage difference between a bitline and a complementary bitline includes an N-type sense amplifier connected to the bitline and the complementary bitline, a P-type sense amplifier including a first PMOS transistor having a first impurity region and connected to the N-type sense amplifier through a first sensing bitline and a first complementary sensing bitline, and a level balancing transistor including a first impurity region and connecting the first sensing bitline and the first complementary sensing bitline based on a level balancing control signal, wherein the first impurity region of the level balancing transistor and the first impurity region of the first PMOS transistor are a first common impurity region shared between the level balancing transistor and the first PMOS transistor.

### CROSS-REFERENCE TO RELATED APPLICATION

This application claims priority to Korean Patent Application No. 10-2025-0052471, filed in the Korean Intellectual Property Office on Apr. 22, 2025, the entire contents of which are hereby incorporated by reference.

### BACKGROUND

### Field

The present disclosure relates to a memory device, and more specifically, to a memory device including a bitline sense amplifier.

### Description of Related Art

Semiconductor memory devices may be broadly classified into volatile memory and non-volatile memory. Volatile memory may have the characteristic of fast read and write speeds, but stored data may disappear when power supply is interrupted. Non-volatile memory may have the characteristic of continuously preserving data even when power supply is interrupted.

A representative example of volatile memory is dynamic random access memory (DRAM). A memory cell of a DRAM may include one NMOS transistor serving as a switch and one capacitor storing data. Depending on the presence or absence of charge stored in the capacitor of the memory cell, binary information “1” or “0” may be assigned, and data may be distinguished through a voltage difference of the capacitor. The memory cell may be connected to a wordline and a bitline. The bitline may be connected to a bitline sense amplifier, and the bitline sense amplifier may sense data stored in the memory cell through the bitline based on a voltage applied to the wordline.

Meanwhile, as electronic products are desirable to be miniaturized, multi-functional, and high-performance, the demand for high-capacity integrated circuit devices is increasing. To this end, the integration density of integrated circuit devices is increasing, and the feature size of transistors is gradually decreasing. Due to this miniaturization trend, in memory devices such as DRAM devices, a decrease in gate length and a deviation in threshold voltage of transistors may affect characteristics of transistors included in the bitline sense amplifier.

The information described above is provided to enhance understanding of the background of the present disclosure and may include information that does not constitute prior art.

### SUMMARY

The present disclosure relates to a memory device for solving the above problems.

The problems to be solved by the present disclosure are not limited to those described above, and other unmentioned problems may be clearly understood by those of ordinary skill in the art from the following description of the disclosure.

According to an aspect of the present disclosure, a memory device comprising a bitline sense amplifier sensing a voltage difference between a bitline and a complementary bitline. The bitline sense amplifier includes an N-type sense amplifier connected to the bitline and the complementary bitline, a P-type sense amplifier including a first PMOS transistor having a first impurity region as one of a pair of source/drain regions of the first PMOS transistor and connected to the N-type sense amplifier through a first sensing bitline and a first complementary sensing bitline, and a level balancing transistor including a first impurity region as one of a pair of source/drain regions of the level balancing transistor and connecting the first sensing bitline and the first complementary sensing bitline based on a level balancing control signal. The first impurity region of the level balancing transistor and the first impurity region of the first PMOS transistor are a first common impurity region shared between the level balancing transistor and the first PMOS transistor.

According to an aspect of the present disclosure, a memory device includes a bitline sense amplifier sensing a voltage difference between a bit line and a complementary bitline, and a substrate on which a first PMOS active region, a second PMOS active region, and a connected active region connected to the first PMOS active region and the second PMOS active region are defined. The bitline sense amplifier includes an N-type sense amplifier connected to the bitline and the complementary bitline, a P-type sense amplifier connected to the N-type sense amplifier through a first sensing bitline and a first complementary sensing bitline, and a level balancing transistor connecting the first sensing bitline and the first complementary sensing bitline based on a level balancing control signal. The P-type sense amplifier includes a first PMOS transistor having a first gate electrode pattern connected to the first sensing bitline, and a second PMOS transistor having a second gate electrode pattern connected to the first complementary sensing bitline. The level balancing transistor includes a level balancing gate pattern disposed on the connected active region and comprising a pair of sidewalls spaced apart in a first direction parallel to an upper surface of the substrate and extending in a second direction parallel to the upper surface of the substrate and intersecting the first direction, a first common impurity region disposed on the upper surface of the substrate as one of a pair of source/drain regions of the level balancing transistor and adjacent to one of the pair of sidewalls of the level balancing gate pattern, and a second common impurity region disposed on the upper surface of the substrate as the other of the pair of source/drain regions of the level balancing transistor and adjacent to the other of the pair of sidewalls of the level balancing gate pattern. The level balancing transistor shares the first common impurity region with the first PMOS transistor and shares the second common impurity region with the second PMOS transistor.

According to an aspect of the present disclosure, a memory device includes a bitline sense amplifier sensing a voltage difference between a bitline and a complementary bitline, and a substrate on which a first PMOS active region, a second PMOS active region, a connected active region connected to the first PMOS active region and the second PMOS active region are defined. The bitline sense amplifier includes an N-type sense amplifier connected to the bitline and the complementary bitline, a P-type sense amplifier connected to the N-type sense amplifier through a first sensing bitline and a first complementary sensing bitline, and a level balancing transistor connecting the first sensing bitline and the first complementary sensing bitline based on a level balancing control signal. The P-type sense amplifier includes a first PMOS transistor having a first gate electrode pattern connected to the first sensing bitline, and a second PMOS transistor having a second gate electrode pattern connected to the first complementary sensing bitline. The level balancing transistor, when viewed in a plan view, is disposed in a space between the first PMOS transistor and the second PMOS transistor. The level balancing transistor includes a level balancing gate pattern disposed on the connected active region and comprising a pair of sidewalls spaced apart in a first direction parallel to an upper surface of the substrate and extending in a second direction parallel to the upper surface of the substrate and intersecting the first direction, a first common impurity region disposed on the upper surface of the substrate as one of a pair of source/drain regions of the level balancing transistor and adjacent to one of the pair of sidewalls of the level balancing gate pattern, and a second common impurity region disposed on the upper surface of the substrate as the other of the pair of source/drain regions of the level balancing transistor and adjacent to the other of the pair of sidewalls of the level balancing gate pattern. The first PMOS transistor includes the first gate pattern disposed on the first PMOS active region and comprising a first rectangular main region having a pair of first long sidewalls extending in the first direction and a pair of first short sidewalls extending in the second direction, and a first rectangular extended region extending in the second direction from one of the pair of first long sidewalls of the first rectangular main region, a first impurity region disposed on the upper surface of the substrate as one of a pair of source/drain regions of the first PMOS transistor and adjacent to the other of the pair of first long sidewalls of the first rectangular main region, and the first common impurity region as the other of the pair of source/drain regions of the first PMOS transistor. The first common impurity region is disposed adjacent to one of the pair of first short sidewalls of the first rectangular main region. The second PMOS transistor includes the second gate pattern disposed on the second PMOS active region and comprising a second rectangular main region having a pair of second long sidewalls extending in the first direction and a pair of second short sidewalls extending in the second direction, and a second rectangular extended region extending in the second direction from one of the pair of second long sidewalls of the second rectangular main region, a second impurity region disposed on the upper surface of the substrate as one of a pair of source/drain regions of the second PMOS transistor and adjacent to the other of the pair of second long sidewalls of the second rectangular main region, and the second common impurity region as the other of the pair of source/drain regions of the second PMOS transistor. The second common impurity region is adjacent to one of the pair of second short sidewalls of the second rectangular main region. When viewed in a plan view, the connected active region is disposed between the first PMOS active region and the second PMOS active region. The first common impurity region is disposed at a boundary between the first PMOS active region and the connected active region, and the second common impurity region is disposed at a boundary between the second PMOS active region and the connected active region.

According to various embodiments of the present disclosure, in the bitline sense amplifier of the memory device, since the transistor connecting the sensing bitline and the complementary sensing bitline is implemented as a PMOS transistor, an effective arrangement structure for securing an effective gate length of a gate pattern may be implemented.

According to various embodiments of the present disclosure, as the effective gate length of the gate pattern increases, characteristics of transistors included in the P-type sense amplifier and/or the N-type sense amplifier may be effectively improved in the bitline sense amplifier of the memory device. For example, control of leakage current (or off-current) of the transistor becomes easy, and mismatch between paired transistors may be improved by securing uniformity as the effective gate length increases. Due to this, offset noise that may occur in the bitline sense amplifier may be effectively improved.

According to various embodiments of the present disclosure, the number of contacts included in the bitline sense amplifier of the memory device may be effectively reduced by optimizing the arrangement structure of transistors. Due to this, a region occupied by the contacts may be secured, and the gate pattern length of the transistors may be increased, thereby effectively improving electrical characteristics of the transistors, for example, leakage current control or mismatch between transistors.

In addition, since some process steps related to contact formation may be simplified or reduced, mismatch between transistors due to process variations may be effectively improved. Furthermore, since more free space is secured within the same area due to the reduction in the number of contacts, the integration density of the entire memory device may also be improved.

According to various embodiments of the present disclosure, since the transistor connecting the sensing bitline and the complementary sensing bitline is implemented as a PMOS transistor, a signal controlling the transistor may be stably driven at a relatively low voltage, thereby providing a structure advantageous for low-voltage design of the entire circuit.

The effects that may be obtained through the present disclosure are not limited to those described above. Other unmentioned technical effects will be clearly understood by those of ordinary skill in the art from the description of the disclosure described below.

### BRIEF DESCRIPTION OF THE DRAWINGS

FIG. 1 is a block diagram illustrating a memory system according to some embodiments of the present disclosure.

FIG. 2 is a diagram illustrating a memory device according to some embodiments of the present disclosure.

FIG. 3 is a diagram illustrating a memory cell connected to a sense amplifier array according to some embodiments of the present disclosure.

FIG. 4 is a diagram illustrating a memory cell array to which a bitline sense amplifier is connected according to some embodiments of the present disclosure.

FIG. 5 is a diagram illustrating a bitline sense amplifier according to some embodiments of the present disclosure.

FIG. 6 is a timing diagram illustrating an operation of a bitline sense amplifier according to some embodiments of the present disclosure.

FIG. 7 is a diagram illustrating a layout of a bitline sense amplifier according to some embodiments of the present disclosure.

FIG. 8 is an enlarged view of portion A of FIG. 7.

FIG. 9 is a diagram illustrating a layout of a bitline sense amplifier according to some embodiments of the present disclosure.

FIG. 10 is an enlarged view of portion B of FIG. 9.

FIG. 11 is a diagram illustrating a layout of a bitline sense amplifier according to some embodiments of the present disclosure.

FIG. 12 is an enlarged view of portion C of FIG. 11.

FIG. 13 is a diagram illustrating a layout of a bitline sense amplifier according to some embodiments of the present disclosure.

FIG. 14 is an enlarged view of portion D of FIG. 13.

FIG. 15 is a diagram illustrating differences according to a design of a level balancing transistor according to some embodiments of the present disclosure.

FIGS. 16 and 17 are diagrams illustrating a memory device to which a bitline sense amplifier is applied according to some embodiments of the present disclosure.

FIG. 18 is a diagram illustrating an example where a memory device including a bitline sense amplifier according to some embodiments of the present disclosure is applied to a mobile device.

### DETAILED DESCRIPTION

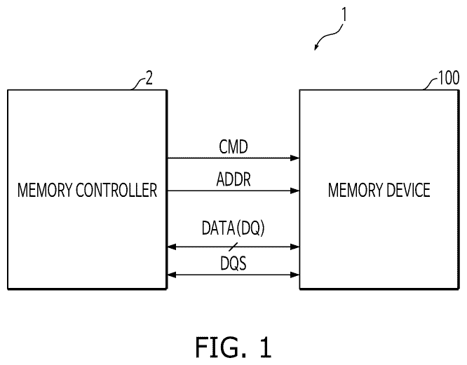

Hereinafter, various embodiments of the present disclosure will be described with reference to FIGS. 1 to 18. The same reference numerals may refer to the same components throughout the specification.

FIG. 1 illustrates a memory system according to some embodiments of the present disclosure.

Referring to FIG. 1, a memory system 1 may include a memory controller 2 and a memory device 100.

The memory controller 2 may perform an operation of writing data DATA to the memory device 100 or reading data DATA stored in the memory device 100. For example, the memory controller 2 may generate a command CMD and an address ADDR for writing data DATA to the memory device 100 or reading data DATA stored in the memory device 100. In some embodiments, the memory controller 2 may be at least one of a memory controller for controlling the memory device 100, a system on chip (SoC) such as an application processor (AP), a central processing unit (CPU), a digital signal processor (DSP), or a graphics processing unit (GPU).

The memory device 100 may store data DATA received through a plurality of data lines DQ or transmit data DATA stored in the memory device 100 to the memory controller 2 through the plurality of data lines DQ according to control of the memory controller 2. The memory device 100 may transmit the data DATA to the memory controller 2 in synchronization with a data strobe signal provided through a data strobe line DQS. For example, between the memory device 100 and the memory controller 2, the data DATA may be transmitted and received through the plurality of data lines DQ and the data strobe line DQS.

In some embodiments, the memory device 100 may include dynamic random access memory (DRAM). However, the scope of the present disclosure is not limited to thereto, and the memory device 100 may include at least one of various memory devices such as SRAM (Static RAM), SDRAM (Synchronous DRAM), ROM (Read Only Memory), PROM (Programmable ROM), EPROM (Electrically Programmable ROM), EEPROM (Electrically Erasable and Programmable ROM), a flash memory device, PRAM (Phase-change RAM), MRAM (Magnetic RAM), RRAM (Resistive RAM), and FRAM (Ferroelectric RAM).

In some embodiments, the memory device 100 and the memory controller 2 may communicate based on a DDR (Double Data Rate) interface, but the scope of the present disclosure is not limited thereto. For example, the memory device 100 and the memory controller 2 may communicate based on at least one of various interfaces such as USB (Universal Serial Bus), MMC (MultiMedia Card), PCI (Peripheral Component Interconnection), PCI-E (PCI-express), ATA (Advanced Technology Attachment), SATA (Serial-ATA), PATA (Parallel-ATA), SCSI (Small Computer Small Interface), ESDI (Enhanced Small Disk Interface), IDE (Integrated Drive Electronics), MIPI (Mobile Industry Processor Interface), NVMe (Nonvolatile Memory-express), and a NAND interface.

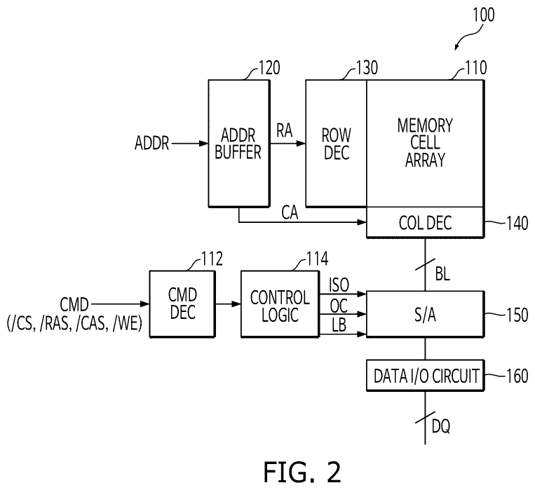

FIG. 2 is a diagram illustrating a memory device according to some embodiments of the present disclosure.

Referring to FIG. 2, the memory device 100 may include a memory cell array 110, a command decoder 112, control logic 114, an address buffer 120, a row decoder 130, a column decoder 140, a sense amplifier array 150, and a data input/output circuit 160.

The memory cell array 110 may include a plurality of memory cells provided in a matrix form arranged in rows and columns. The memory cell array 110 may include a plurality of wordlines and a plurality of bitlines BL connected to the memory cells. The plurality of wordlines may be connected to the rows of the memory cells, and the plurality of bitlines BL may be connected to the columns of the memory cells.

The command decoder 112 may decode an input command CMD with reference to a chip select signal/CS, a row address strobe signal/RAS, a column address strobe signal /CAS, a write enable signal/WE, etc., received from a memory controller (e.g., the memory controller 2 of FIG. 1). The command CMD may include an active command, a read command, a write command, a precharge command, and the like.

The control logic 114 may generate various control signals for an access operation, for example, a write operation, a read operation, a precharge operation, etc., for the memory cell array 110 in response to the decoded command. The control logic 114 may control overall operation of the sense amplifier array 150 through the control signals.

The address buffer 120 may receive the address ADDR from the memory controller. The address ADDR may include a row address RA for addressing a row of the memory cell array 110 and a column address CA for addressing a column of the memory cell array 110. The address buffer 120 may transmit the row address RA to the row decoder 130 and transmit the column address CA to the column decoder 140.

The row decoder 130 may select any one of a plurality of wordlines connected to the memory cell array 110. The row decoder 130 may decode the row address RA received from the address buffer 120, select a wordline corresponding to the row address RA, and activate the selected wordline. During a wordline enable operation where the wordline is activated, a high power supply voltage greater than a power supply voltage may be applied to a gate of a cell transistor of the memory cell. In the present application, the term “a gate” or “a gate pattern” can be referred to as “a gate electrode pattern.”

The column decoder 140 may select any one of a plurality of bitlines BL connected to the memory cell array 110. The column decoder 140 may decode the column address CA received from the address buffer 120 and select a bitline BL corresponding to the column address CA.

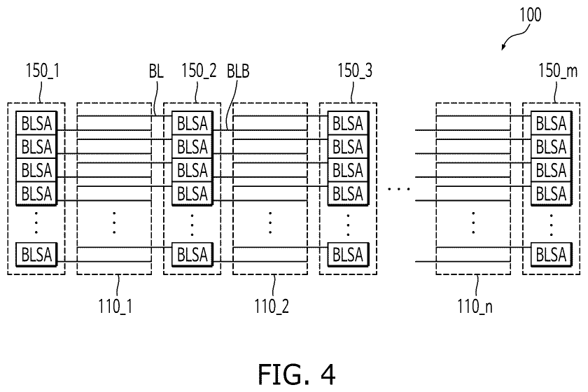

The sense amplifier array 150 may be connected to the bitlines BL of the memory cell array 110. The sense amplifier array 150 may sense a voltage change of a selected bitline among the plurality of bitlines BL and amplify and output the sensed voltage change. Each bitline sense amplifier included in the sense amplifier array 150 may be connected to a bitline BL and a complementary bitline to sense and amplify a voltage change of the bitline BL. For example, each bitline sense amplifier may sense and amplify a voltage difference between the bitline BL and its complementary bitline. Specific details related to this will be described later with reference to FIG. 4.

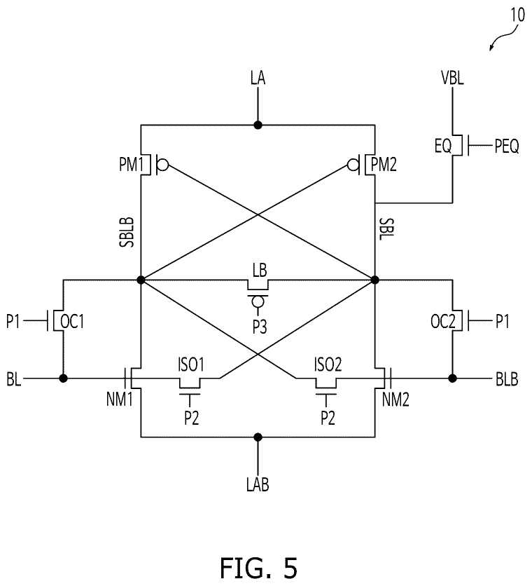

In some embodiments, the sense amplifier array 150 may receive an isolation signal ISO, an offset cancel signal OC, a level balancing signal LB, and the like from the control logic 114. The sense amplifier array 150 may perform an offset cancellation operation based on receiving the isolation signal ISO, the offset cancel signal OC, the level balancing signal LB, and the like. For example, the offset may refer to a difference in characteristics, for example, threshold voltage, between semiconductor devices included in the sense amplifier array 150 (e.g., mismatch between threshold voltages of transistors NM1 and NM2 or mismatch between threshold voltages of transistors PM1 and PM2 as shown in FIG. 5). In addition, the sense amplifier array 150 may perform a level balancing operation that maintains voltage levels equally based on the level balancing signal LB.

The data input/output circuit 160 may output data output based on the sensed and amplified voltage from the sense amplifier array 150 to an external device (e.g., a memory controller, etc.) through the data lines DQ. In addition, the data input/output circuit 160 may receive write data from the external device through the data lines DQ.

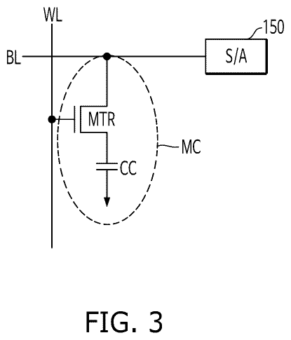

FIG. 3 is a diagram illustrating a memory cell connected to a sense amplifier array according to some embodiments of the present disclosure.

Referring to FIG. 3, one memory cell MC included in a memory cell array (e.g., the memory cell array 110 of FIG. 2) may include a cell transistor MTR and a cell capacitor CC. One end of the cell transistor MTR may be connected to a bitline BL. The other end of the cell transistor MTR may be connected to the cell capacitor CC. A gate of the cell transistor MTR may be connected to a wordline WL. In the present disclosure, the terms “one end” and “the other end” of a transistor may refer to a pair of source/drain regions or terminals of the transistor. For example, when the one end of the transistor serves as one of the pair of source/drain regions, the other end of the transistor serves as the other of the pair of source/drain regions, and vice versa.

A memory device (e.g., the memory device 100 of FIG. 2) may perform a read operation to read a charge amount of the cell capacitor CC included in the memory cell MC or a refresh operation to restore the charge amount of the cell capacitor CC. At this time, the bitline BL connected to the memory cell MC may be precharged with a precharge voltage. Thereafter, as the wordline WL is activated, a charge sharing operation may occur between a charge of the bitline BL charged with the precharge voltage and a charge of the cell capacitor CC of the memory cell MC. A voltage of the bitline BL may decrease or increase by a voltage change amount from the precharge voltage due to the charge sharing operation. Each bitline sense amplifier in the sense amplifier array 150 may sense the voltage change amount of the bitline BL and amplify it.

FIG. 4 is a diagram illustrating a memory cell array to which a bitline sense amplifier is connected according to some embodiments of the present disclosure.

Referring to FIG. 4, the memory device 100 may include a plurality of memory cell arrays 110_1, 110_2, . . . , 110_n, where n is a natural number greater than or equal to 3, and a plurality of sense amplifiers 150_1, 150_2, 150_3, . . . , 150_m, where m is a natural number greater than or equal to 4. The number m is greater than the number n by one.

Each of the plurality of sense amplifiers 150_1, 150_2, 150_3, . . . , 150_m may include a plurality of bitline sense amplifiers (hereinafter, ‘BLSA’). The bitline sense amplifiers BLSA may be implemented as the sense amplifier array 150 described in FIGS. 2 to 3.

The plurality of bitlines BL and the plurality of complementary bitlines BLB connected to the plurality of memory cell arrays 110_1, 110_2, . . . , 110_n may each be connected to the plurality of bitline sense amplifiers BLSA. For example, each of the plurality of bitline sense amplifiers BLSA may be a cross-coupled differential sense amplifier implemented as a P-type sense amplifier and an N-type sense amplifier.

Each of the plurality of bitline sense amplifiers BLSA may be distinguished from dummy sense amplifiers 150_1, 150_m implemented in a region other than a region where the bitline sense amplifiers 150_2, 150_3, . . . , 150_m-1 are implemented, as circuit elements that operate normally during operation of the semiconductor memory device. For example, each of the plurality of bitline sense amplifiers BLSA may have an open bitline sense amplifier architecture in which a bitline and a complementary bitline are connected to opposite sides of the bitline sense amplifier BLSA, respectively. The bitline sense amplifiers 150_1, 150_m positioned at the edge of a region where the plurality of bitline sense amplifiers BLSA are disposed may be connected to only one of a pair of a bitline and a complementary bitline. The bitline sense amplifiers 150_1, 150_m positioned at the edge of the memory device 100 may be referred to as the dummy sense amplifiers not working as a bitline sense amplifier.

In some embodiments, an odd-numbered bitline of each of the plurality of memory cell arrays 110_1, 110_2, . . . , 110_n may be connected to a bitline BL, and an even-numbered bitline may be connected to a complementary bitline BLB. The bitline sense amplifier BLSA may be connected to a bitline pair BL, BLB in both directions. For example, the sense amplifier 150_2 may be connected to an odd-numbered bitline, that is, a bitline BL of a first memory cell array 110_1 on the left side, and the sense amplifier 150_2 may be connected to an even-numbered bitline, that is, a complementary bitline BLB of a second memory cell array 110_2 on the right side.

In a sensing operation of the bitline sense amplifier BLSA, when a potential of the bitline BL is a high potential, a potential of the complementary bitline BLB may be a low potential. In contrast, in the sensing operation of the bitline sense amplifier BLSA, when the potential of the bitline BL is a low potential, the potential of the complementary bitline BLB may be a high potential.

FIG. 5 is a diagram illustrating a bitline sense amplifier according to some embodiments of the present disclosure. Here, a bitline sense amplifier 10 may correspond to one bitline sense amplifier connected to one bitline and one complementary bitline among the sense amplifier array 150 of FIG. 2.

Referring to FIG. 5, the bitline sense amplifier 10 may include an N-type sense amplifier and a P-type sense amplifier. For example, the N-type sense amplifier may include N-type transistors (e.g., a first NMOS (N-type Metal-Oxide-Semiconductor) transistor NM1 and a second NMOS transistor NM2). In addition, the P-type sense amplifier may include P-type transistors (e.g., a first PMOS (P-type Metal-Oxide-Semiconductor) transistor PM1 and a second PMOS transistor PM2). The first PMOS transistor PM1 and the second PMOS transistor PM2, and the first NMOS transistor NM1 and the second NMOS transistor NM2 may be connected in a cross-coupled structure. The N-type sense amplifier and the P-type sense amplifier may amplify a voltage change amount of a bitline BL according to a predetermined ratio during a bitline sensing operation.

In some embodiments, the N-type sense amplifier may be connected between a control line LA to which a first control signal is supplied and a complementary control line LAB to which a second control signal is supplied, and between the bitline BL and a complementary bitline BLB. The P-type sense amplifier may be connected between the control line LA to which the first control signal is supplied and the N-type sense amplifier. The P-type sense amplifier may be connected to the N-type sense amplifier through a sensing bitline SBL and a complementary sensing bitline SBLB.

In some embodiments, the bitline sense amplifier 10 may include a plurality of transistors.

A first offset transistor OC1 may be connected between the bitline BL and the complementary sensing bitline SBLB. The first offset transistor OC1 may connect or disconnect the bitline BL and the complementary sensing bitline SBLB based on an offset control signal P1. A second offset transistor OC2 may be connected between the complementary bitline BLB and the sensing bitline SBL. The second offset transistor OC2 may connect or disconnect the complementary bitline BLB and the sensing bitline SBL based on the offset control signal P1.

A first isolation transistor ISO1 may be connected between the bitline BL and the sensing bitline SBL. The first isolation transistor ISO1 may connect or disconnect the bitline BL and the sensing bitline SBL based on an isolation control signal P2. A second isolation transistor ISO2 may be connected between the complementary bitline BLB and the complementary sensing bitline SBLB. The second isolation transistor ISO2 may connect or disconnect the complementary bitline BLB and the complementary sensing bitline SBLB based on the isolation control signal P2.

A level balancing transistor LB may be connected between the sensing bitline SBL and the complementary sensing bitline SBLB. The level balancing transistor LB may connect or disconnect the sensing bitline SBL and the complementary sensing bitline SBLB based on a level balancing control signal P3.

An equalization transistor EQ may be connected between a line to which a precharge voltage VBL is applied and the sensing bitline SBL. The equalization transistor EQ may connect or disconnect the line to which the precharge voltage VBL is applied and the sensing bitline SBL based on an equalization signal PEQ.

In some embodiments, the N-type sense amplifier and the P-type sense amplifier may sense and amplify a voltage difference between the bitline BL and the complementary bitline BLB based on a voltage applied to the control line LA and the complementary control line LAB.

One end of the first PMOS transistor PM1 may be connected to the control line LA, the other end of the first PMOS transistor PM1 may be connected to the complementary sensing bitline SBLB, and a gate of the first PMOS transistor PM1 may be connected to the sensing bitline SBL. One end of the second PMOS transistor PM2 may be connected to the control line LA, the other end of the second PMOS transistor PM2 may be connected to the sensing bitline SBL, and a gate of the second PMOS transistor PM2 may be connected to the complementary sensing bitline SBLB. One end of the first NMOS transistor NM1 may be connected to the complementary sensing bitline SBLB, the other end of the first NMOS transistor NM1 may be connected to the complementary control line LAB, and the gate of the first NMOS transistor NM1 may be connected to the bitline BL. One end of the second NMOS transistor NM2 may be connected to the sensing bitline SBL, the other end of the second NMOS transistor NM2 may be connected to the complementary control line LAB, and the gate of the second NMOS transistor NM2 may be connected to the complementary bitline BLB.

In some embodiments, the level balancing transistor LB may share a common impurity region with a P-type sense amplifier. For example, the level balancing transistor LB may share a common impurity region with at least one of the first PMOS transistor PM1 or the second PMOS transistor PM2.

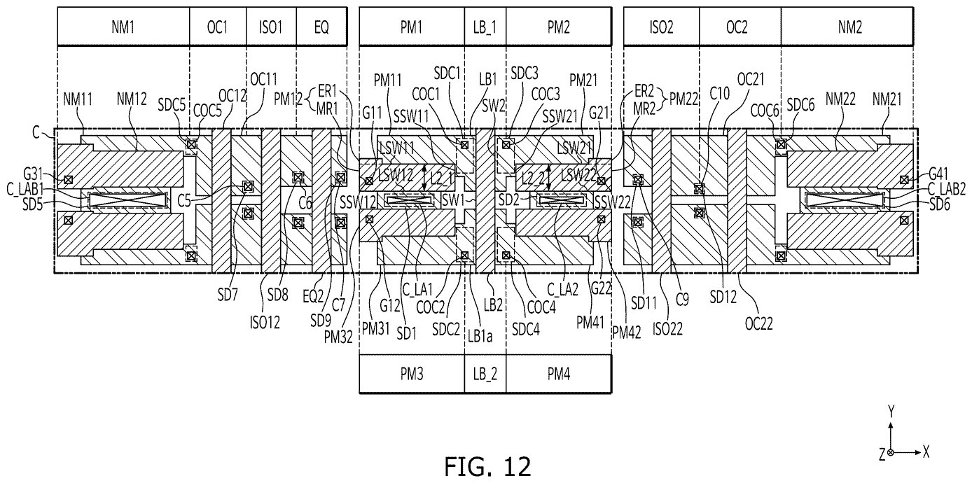

In some embodiments, one end of the level balancing transistor LB and the other end of the first PMOS transistor PM1 may be connected to the complementary sensing bitline SBLB. Here, the level balancing transistor LB and the first PMOS transistor PM1 may share a common impurity region (e.g., a common impurity region SDC1, see FIG. 12). For example, the one end of the level balancing transistor LB and the other end of the first PMOS transistor PM1 may be configured as a portion of the same active region.

In some embodiments, the other end of the level balancing transistor LB and the other end of the second PMOS transistor PM2 may be connected to the sensing bitline SBL. Here, the level balancing transistor LB and the second PMOS transistor PM2 may share a common impurity region (e.g., a common impurity region SDC3, see FIG. 12). For example, the other end of the level balancing transistor LB and the other end of the second PMOS transistor PM2 may be configured as a portion of the same active region.

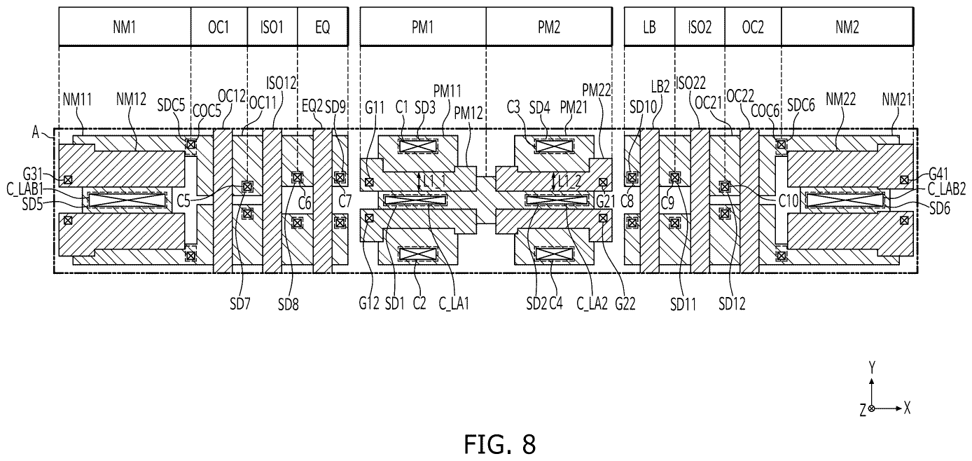

In some embodiments, the first NMOS transistor NM1 may share a common impurity region (e.g., a common impurity region SDC5, see FIG. 8) with the first offset transistor OC1. For example, one end of the first NMOS transistor NM1 and one end of the first offset transistor OC1 may be configured as a portion of the same active region. In some embodiments, the second NMOS transistor NM2 may share a common impurity region (e.g., a common impurity region SDC6, see FIG. 8) with the second offset transistor OC2. For example, one end of the second NMOS transistor NM2 and one end of the second offset transistor OC2 may be configured as a portion of the same active region.

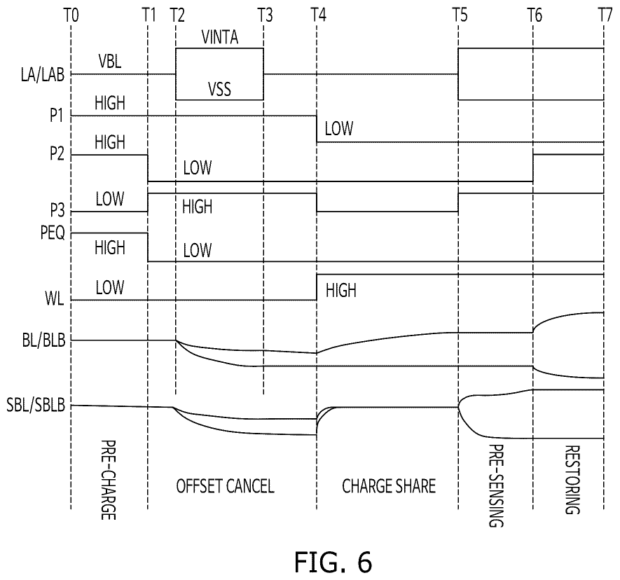

FIG. 6 is a timing diagram illustrating an operation of a bitline sense amplifier according to some embodiments of the present disclosure. The operation of the bitline sense amplifier will be described with reference to FIG. 5.

The x-axis of FIG. 6 indicates time, and the y-axis indicates a signal level. For example, it is assumed that data ‘1’ is stored in a memory cell, and the memory device has a predetermined offset voltage due to a threshold voltage difference between a pair of transistors included in a bitline sense amplifier.

Referring to FIG. 6, a bitline sense amplifier (e.g., the bitline sense amplifier 10 of FIG. 5) may perform a precharge operation (PRE-CHARGE), an offset cancel operation (OFFSET CANCEL), a charge sharing operation (CHARGE SHARE), a pre-sensing operation (PRE-SENSING), and a restoring operation (RESTORING). For example, the bitline sense amplifier may perform the precharge operation (PRE-CHARGE) between time T0 and time T1, perform the offset cancel operation (OFFSET CANCEL) between time T1 and time T4, perform the charge sharing operation (CHARGE SHARE) between time T4 and time T5, perform the pre-sensing operation (PRE-SENSING) between time T5 and time T6, and perform the restoring operation (RESTORING) between time T6 and time T7.

In a first interval from time T0 to time T1, the bitline sense amplifier may perform a precharge operation (PRE-CHARGE).

In the first interval, the offset control signal P1 may be logic high. A first offset transistor (e.g., the offset transistor OC1 of FIG. 5) and a second offset transistor (e.g., the offset transistor OC2 of FIG. 5) may be turned on in response to the offset control signal P1. Accordingly, the bitline BL and the complementary sensing bitline SBLB as shown in FIG. 5 may be connected, and the complementary bitline BLB and the sensing bitline SBL as shown in FIG. 5 may be connected.

In addition, in the first interval, the isolation control signal P2 may be logic high. A first isolation transistor (e.g., the isolation transistor ISO1 of FIG. 5) and a second isolation transistor (e.g., the isolation transistor ISO2 of FIG. 5) may be turned on in response to the isolation control signal P2. Accordingly, the bitline BL and the sensing bitline SBL may be connected, and the complementary bitline BLB and the complementary sensing bitline SBLB may be connected.

In addition, in the first interval, when a level balancing transistor is an N-type transistor, the level balancing control signal P3 may be logic high. The level balancing transistor LB may be turned on in response to the level balancing control signal P3. As shown in FIG. 5, when the level balancing transistor LB is a P-type transistor, the level balancing control signal P3 may be logic low. The level balancing transistor LB may be turned on in response to the level balancing control signal P3. When the level balancing transistor is implemented as an N-type transistor, a complementary logic level of the level balancing control signal P3 as shown in FIG. 6 is applied. Accordingly, the sensing bitline SBL and the complementary sensing bitline SBLB may be connected.

In addition, in the first interval, the equalization signal PEQ may be logic high. An equalization transistor (e.g., the equalization transistor EQ of FIG. 5) may be turned on in response to the equalization signal PEQ.

In addition, in the first interval, the precharge voltage VBL may be applied to the control line LA and the complementary control line LAB. Accordingly, the bitline BL, the complementary bitline BLB, the sensing bitline SBL, and the complementary sensing bitline SBLB may be precharged with the precharge voltage VBL.

In a second interval from time T1 to time T4, the bitline sense amplifier may perform an offset cancellation operation (OFFSET CANCEL).

In the second interval, the offset control signal P1 may be maintained at logic high, the isolation control signal P2 and the equalization signal PEQ may be changed to logic low, and the level balancing control signal P3 may be changed to logic high. Accordingly, the first and second isolation transistors ISO1 and ISO2 may be turned off in response to the isolation control signal P2, the level balancing transistor LB may be turned off in response to the level balancing control signal P3, and the equalization transistor may be turned off in response to the equalization signal PEQ. Due to this, the bitline BL and the sensing bitline SBL may be separated, the complementary bitline BLB and the complementary sensing bitline SBLB may be separated, and the sensing bitline SBL and the complementary sensing bitline SBLB may be separated.

Meanwhile, due to process variations, temperature, etc., a threshold voltage difference may occur between transistor pairs included in the bitline sense amplifier, for example, a pair of a first PMOS transistor (e.g., the PMOS transistor PM1 of FIG. 5) and a second PMOS transistor (e.g., the PMOS transistor PM2 of FIG. 5), or a pair of a first NMOS transistor (e.g., the NMOS transistor NM1 of FIG. 5) and a second NMOS transistor (e.g., the NMOS transistor NM2 of FIG. 5). In this case, during a sensing process of the bitline sense amplifier, offset noise due to the threshold voltage difference between the PMOS transistor pair or the NMOS transistor pair may occur.

At time T2, a power supply voltage VINTA may be applied to the control line LA, and a ground voltage VSS may be applied to the complementary control line LAB. In addition, at time T3, the precharge voltage VBL may be applied to the control line LA and the complementary control line LAB. For example, the power supply voltage VINTA may be a voltage supplied to a memory cell array.

During the second interval, the bitline BL and the complementary bitline BLB may have a predetermined voltage difference. This voltage difference may be interpreted as an offset voltage due to offset noise caused by a threshold voltage difference between a pair of transistors included in the bitline sense amplifier. By storing the bitline BL and the complementary bitline BLB with a voltage difference equal to the offset voltage, offset noise of the bitline sense amplifier may be removed.

In a third interval from time T4 to time T5, the bitline sense amplifier may perform a charge sharing operation (CHARGE SHARE).

In the third interval, the offset control signal P1 may be changed to logic low, the isolation control signal P2 and the equalization signal PEQ may be maintained at logic low, and the level balancing control signal P3 may be changed to logic low. Accordingly, the first and second offset transistors may be turned off in response to the offset control signal P1, and the level balancing transistor LB may be turned on in response to the level balancing control signal P3. Due to this, the bitline BL and the complementary sensing bitline SBLB may be separated, a complementary bitline BLB and the sensing bitline SBL may be separated, and the sensing bitline SBL and the complementary sensing bitline SBLB may be connected. As the level balancing transistor LB is turned on, the sensing bitline SBL and the complementary sensing bitline SBLB may have the same voltage level.

In the third interval, the wordline WL connected to a memory cell (e.g., the memory cell MC of FIG. 3) may be activated. Due to this, charge sharing may occur between charge stored in a cell capacitor (e.g., the capacitor C of FIG. 3) of the memory cell and charge stored in the bitline BL. When data ‘1’ is stored in the memory cell, a voltage level of the bitline BL may rise by a predetermined level during the charge sharing operation. In contrast, when data ‘0’ is stored in the memory cell, the voltage level of the bitline BL may decrease by a predetermined level during the charge sharing operation.

In a fourth interval from time T5 to time T6, the bitline sense amplifier may perform a pre-sensing operation (PRE-SENSING).

In the fourth interval, the offset control signal P1, the isolation control signal P2, and the equalization signal PEQ may be maintained at logic low, and the level balancing control signal P3 may be changed to logic high. Accordingly, the level balancing transistor LB may be turned off in response to the level balancing control signal P3. Due to this, the sensing bitline SBL and the complementary sensing bitline SBLB may be separated.

At time T5, a power supply voltage VINTA may be applied to the control line LA, and a ground voltage VSS may be applied to the complementary control line LAB. Due to this, the P-type sense amplifier and the N-type sense amplifier included in the bitline sense amplifier may sense and amplify a voltage difference between the bitline BL and the complementary bitline BLB based on a voltage applied to the control line LA and the complementary control line LAB. For example, as shown in FIG. 6, when data ‘1’ is stored in a memory cell, a voltage level of the sensing bitline SBL may increase to the power supply voltage VINTA, and a voltage level of the complementary sensing bitline SBLB may fall to the ground voltage VSS. In contrast, when data ‘0’ is stored in the memory cell, a voltage level of the bitline BL may decrease by a predetermined level during a charge sharing operation. A voltage level of the sensing bitline SBL may fall to the ground voltage VSS, and a voltage level of the complementary sensing bitline SBLB may increase to the power supply voltage VINTA.

In a fifth interval from time T6 to time T7, the bitline sense amplifier may perform a restoring operation (RESTORING).

In the fifth interval, the offset control signal P1 and the equalization signal PEQ may be maintained at logic low, the level balancing control signal P3 may be maintained at logic high, and the isolation control signal P2 may be changed to logic high. Accordingly, the first and second isolation transistors may be turned on in response to the isolation control signal P2. Due to this, the bitline BL and the sensing bitline SBL may be connected, and the complementary bitline BLB and the complementary sensing bitline SBLB may be connected.

During the fifth interval, a voltage level of the bitline BL may be charged or discharged to a voltage level of the sensing bitline SBL, and a voltage level of the complementary bitline BLB may be charged or discharged to a voltage level of the complementary sensing bitline SBLB.

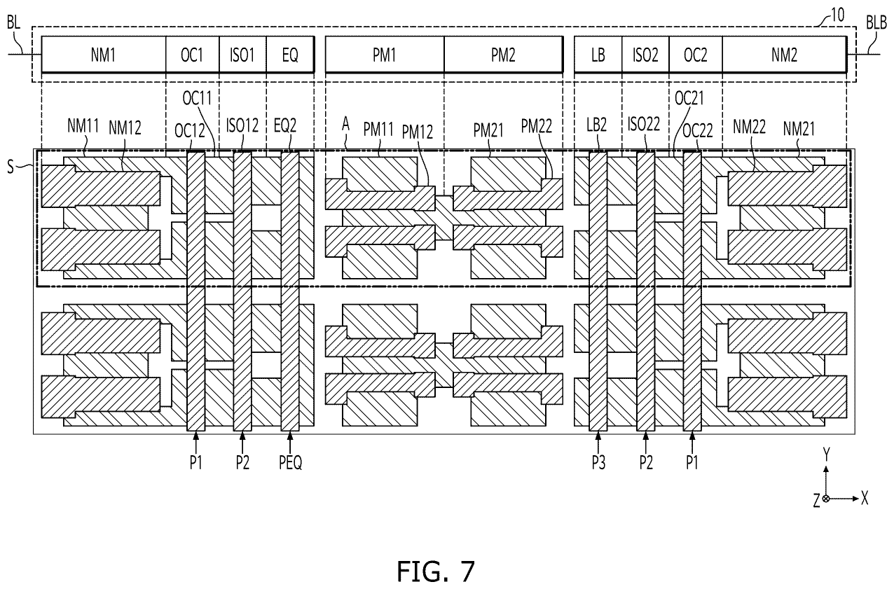

FIG. 7 is a diagram illustrating a layout of a bitline sense amplifier according to some embodiments of the present disclosure. FIG. 8 is an enlarged view of portion A of FIG. 7. FIGS. 7 and 8 will be described with reference to FIG. 5, except that the level balancing transistor LB is an N-type transistor.

Referring to FIG. 7, the bitline sense amplifier 10 may be disposed between the bitline BL and the complementary bitline BLB. The first PMOS transistor PM1 and the second PMOS transistor PM2 may be disposed in a central portion of the bitline sense amplifier 10. In addition, in opposite side portions of the bitline sense amplifier 10, the first NMOS transistor NM1 may be disposed adjacent to the bitline BL, and the second NMOS transistor NM2 may be disposed adjacent to the complementary bitline BLB.

The first PMOS transistor PM1 may include an active region PM11 and a gate pattern PM12, and the second PMOS transistor PM2 may include an active region PM21 and a gate pattern PM22. The active region PM11 of the first PMOS transistor PM1 may be connected to the active region PM21 of the second PMOS transistor PM2, but the scope of the present disclosure is not limited thereto.

The first NMOS transistor NM1 may include an active region NM11 and a gate pattern NM12, and the second NMOS transistor NM2 may include an active region NM21 and a gate pattern NM22.

Between the first NMOS transistor NM1 and the first PMOS transistor PM1, the first offset transistor OC1, the first isolation transistor ISO1, and the equalization transistor EQ may be disposed. The first offset transistor OC1 may be disposed adjacent to the first NMOS transistor NM1, the equalization transistor EQ may be disposed adjacent to the first PMOS transistor PM1, and the first isolation transistor ISO1 may be disposed between the first offset transistor OC1 and the equalization transistor EQ. However, the arrangement of the first offset transistor OC1, the first isolation transistor ISO1, and the equalization transistor EQ is exemplary, and the scope of the present disclosure is not limited thereto.

The first offset transistor OC1 may include an active region OC11 and a gate pattern OC12, the first isolation transistor ISO1 may include the active region OC11 and a gate pattern ISO12, and the equalization transistor EQ may include the active region OC11 and a gate pattern EQ2. In some embodiments, the first offset transistor OC1, the first isolation transistor ISO1, and the equalization transistor EQ may share the active region OC11, but are not limited thereto.

The active region OC11 of the first offset transistor OC1 may be connected to the active region NM11 of the first NMOS transistor NM1. Here, the connection of the active region OC11 to the active region NM11 may mean that the active region OC11 is integrally formed with the active region NM11 without being separated. The active region OC11 and the active region NM11 may correspond to an upper portion of a substrate S included in a memory device (e.g., the memory device 100 of FIG. 2), in which impurity ions are doped to have a predetermined impurity concentration.

Between the second NMOS transistor NM2 and the second PMOS transistor PM2, the level balancing transistor LB, the second isolation transistor ISO2, and the second offset transistor OC2 may be disposed. The level balancing transistor LB may be disposed adjacent to the second PMOS transistor PM2, the second offset transistor OC2 may be disposed adjacent to the second NMOS transistor NM2, and the second isolation transistor ISO2 may be disposed between the level balancing transistor LB and the second offset transistor OC2. However, the arrangement of the level balancing transistor LB, the second isolation transistor ISO2, and the second offset transistor OC2 is exemplary, and the scope of the present disclosure is not limited thereto.

The second offset transistor OC2 may include an active region OC21 and a gate pattern OC22, the second isolation transistor ISO2 may include the active region OC21 and the gate pattern ISO22, and the level balancing transistor LB may include the active region OC21 and a gate pattern LB2. In some embodiments, the second offset transistor OC2, the second isolation transistor ISO2, and the level balancing transistor LB may share the active region OC21, but are not limited thereto.

The active region OC21 of the second offset transistor OC2 may be connected to the active region NM21 of the second NMOS transistor NM2. Here, the connection of the active region OC21 to the active region NM21 may mean that the active region OC21 is integrally formed with the active region NM21 without being separated. The active region OC21 and the active region NM21 may correspond to an upper portion of a substrate S included in a memory device, in which impurity ions are doped to have a predetermined impurity concentration.

In some embodiments, the first offset transistor OC1 may share a common impurity region (e.g., the common impurity region SDC5 of FIG. 8) with the first NMOS transistor NM1. In some embodiments, the second offset transistor OC2 may share a common impurity region (e.g., the common impurity region SDC6 of FIG. 8) with the second NMOS transistor NM2. For example, the first offset transistor OC1 may include an impurity region as a source region or a drain region (i.e., one of a pair of source/drain regions of the first offset transistor OC1), and the first NMOS transistor NM1 may include an impurity region as a source or a drain region (i.e., one of a pair of source/drain regions of the first NMOS transistor NM1). The impurity region of the first offset transistor OC1 and the impurity region of the first NMOS transistor NM1 may be formed as the common source/drain region shared between the first offset transistor OC1 and the first NMOS transistor NM1. Hereinafter, two transistors with a common impurity region refer to the two transistors that are connected by sharing the common impurity region as a common source/drain region and are electrically connected without using any conductive strap or metal interconnect that electrically connects distinct source or drain regions of the two transistors.

The offset control signal P1 may be transmitted to the gate pattern OC12 of the first offset transistor OC1 and the gate pattern OC22 of the second offset transistor OC2, the isolation control signal P2 may be transmitted to the gate pattern ISO12 of the first isolation transistor ISO1 and the gate pattern ISO22 of the second isolation transistor ISO2, the level balancing control signal P3 may be transmitted to the gate pattern LB2 of the level balancing transistor LB, and the equalization signal PEQ may be transmitted to the gate pattern EQ2 of the equalization transistor EQ.

An active region corresponding to the bitline sense amplifier 10 may be defined on an upper side of a substrate S included in a memory device. Here, the definition of the active region on the upper side of the substrate S may mean that the active region is disposed on the upper side of the substrate S in the Z-axis direction of FIG. 7. Meanwhile, in FIG. 7 and the following description, the substrate S is shown as encompassing the entire illustrated region, but this is for convenience of explanation and does not limit the shape of the substrate S.

In FIG. 7, a layout is exemplified where the first NMOS transistor NM1, the first offset transistor OC1, the first isolation transistor ISO1, the equalization transistor EQ, the first PMOS transistor PM1, the second PMOS transistor PM2, the level balancing transistor LB, the second isolation transistor ISO2, the second offset transistor OC2, and the second NMOS transistor NM2 are sequentially arranged along a first direction X, and four sets of these transistors are arranged in a second direction Y. In addition, two adjacent first NMOS transistors NM1 in the second direction Y may share the active region NM11, and two adjacent second NMOS transistors NM2 in the second direction Y may share the active region NM21. Two adjacent first PMOS transistors PM1 in the second direction Y may share the active region PM11, and two adjacent second PMOS transistors PM2 in the second direction Y may share the active region PM21. However, the scope of the present disclosure is not limited thereto. Here, the second direction Y and the first direction X are directions parallel to an upper surface of a substrate S included in a memory device, and the first direction X and the second direction Y may be directions that intersect each other or are substantially perpendicular to each other.

Referring to FIG. 8, a first active region, a second active region, and a third active region may be defined on a substrate (e.g., the substrate S of FIG. 7) included in a memory device. Here, the first active region, the second active region, and the third active region may be defined on the substrate S, and a separate layer may or may not be disposed between the substrate S and the first to third active regions. In addition, the definition of the first active region, the second active region, and the third active region on the substrate S may mean that the first active region, the second active region, and the third active region are disposed on the substrate S based on the third direction Z. The third direction Z may be a direction intersecting the first direction X and the second direction Y.

The first active region, the second active region, and the third active region may be regions formed by doping impurity ions on the upper side of the substrate S. The first active region may include the active region PM11 of the first PMOS transistor PM1 and the active region PM21 of the second PMOS transistor PM2. The second active region may include the active region NM11 of the first NMOS transistor NM1 and the active region OC11 shared by the first offset transistor OC1, the first isolation transistor ISO1, and the equalization transistor EQ. The third active region may include the active region NM21 of the second NMOS transistor NM2 and an active region OC21 shared by the second offset transistor OC2, the second isolation transistor ISO2, and the level balancing transistor LB.

On the active region PM11 of the first PMOS transistor PM1, the gate pattern PM12 may extend along the first direction X, and on the active region PM21 of the second PMOS transistor PM2, the gate pattern PM22 may extend along the first direction X. As shown in FIG. 8, each of the gate pattern PM12 of the first PMOS transistor PM1 and the gate pattern PM22 of the second PMOS transistor PM2 may be formed in a rectangular pattern having a pair of sidewalls extending in the first direction X. In addition, a rectangular pattern extended by a predetermined length in the second direction Y may be formed from a portion of each of one of the pair of sidewalls of the gate pattern PM12 and one of the pair of sidewalls of the gate pattern PM22.

In some embodiments, the gate pattern PM12 of the first PMOS transistor PM1 and the gate pattern PM22 of the second PMOS transistor PM2 may each have an effective gate length L1_1, L1_2.

On the active region NM11 of the first NMOS transistor NM1, the gate pattern NM12 may extend along the first direction X, and on the active region NM21 of the second NMOS transistor NM2, the gate pattern NM22 may extend along the first direction X. As shown in FIG. 8, each of the gate pattern NM12 of the first NMOS transistor NM1 and the gate pattern NM22 of the second NMOS transistor NM2 may be formed in a rectangular pattern having a pair of sidewalls extending in the first direction X. In addition, a rectangular pattern extended by a predetermined length in the second direction Y may be formed from a portion of each of one of the pair of sidewalls of the gate pattern NM12 and one of the pair of sidewalls of the gate pattern NM22.

On the active region OC11 shared by the first offset transistor OC1, the first isolation transistor ISO1, and the equalization transistor EQ, the gate patterns OC12, ISO12, EQ2 may extend along the second direction Y. As shown in FIG. 8, each of the gate pattern OC12 of the first offset transistor OC1, the gate pattern ISO12 of the first isolation transistor ISO1, and the gate pattern EQ2 of the equalization transistor EQ may be formed in a rectangular pattern having a pair of sidewalls extending in the second direction Y.

On the active region OC21 shared by the second offset transistor OC2, the second isolation transistor ISO2, and the level balancing transistor LB, the gate patterns LB2, ISO22, OC22 may extend along the second direction Y. As shown in FIG. 8, each of the gate pattern LB2 of the level balancing transistor LB, the gate pattern ISO22 of the second isolation transistor ISO2, and the gate pattern OC22 of the second offset transistor OC2 may be formed in a rectangular pattern having a pair of sidewalls extending in the second direction Y.

As described above, two first PMOS transistors PM1 may share the active region PM11 in the second direction Y, and two second PMOS transistors PM2 may share the active region PM21 in the second direction Y. Accordingly, two gate patterns PM12 may be disposed spaced apart from each other in the second direction Y on the active region PM11, and two gate patterns PM22 may be disposed spaced apart from each other in the second direction Y on the active region PM21. In addition, two first NMOS transistors NM1 may share the active region NM11 in the second direction Y, and two second NMOS transistors NM2 may share the active region NM21 in the second direction Y. Accordingly, two gate patterns NM12 may be disposed spaced apart from each other in the second direction Y on the active region NM11, and two gate patterns NM22 may be disposed spaced apart from each other in the second direction Y on the active region NM21.

In addition, two adjacent first offset transistors OC1, two first isolation transistors ISO1, and two equalization transistors EQ in the second direction Y do not share the active region OC11 with each other, but may share the gate patterns OC12, ISO12, EQ2. Accordingly, two active regions OC11 may be disposed spaced apart from each other along the second direction Y, and the gate patterns OC12, ISO12, EQ2 may extend in the second direction Y so as to intersect or vertically overlap the two active regions OC11.

In addition, two adjacent level balancing transistors LB, two second isolation transistors ISO2, and two second offset transistors OC2 in the second direction Y do not share an active region OC21 with each other, but may share the gate patterns LB2, ISO22, OC22. Accordingly, two active regions OC21 may be disposed spaced apart from each other along the second direction Y, and the gate patterns LB2, ISO22, OC22 may extend in the second direction Y so as to intersect or vertically overlap the two active regions OC21.

Within the active region PM11 of the first PMOS transistor PM1, impurity regions SD1, SD3 may be respectively disposed adjacent to a pair of sidewalls of the gate pattern PM12. The impurity regions SD1, SD3 and the gate pattern PM12 may constitute the first PMOS transistor PM1. The impurity regions SD1, SD3 may each be a high-concentration doping region doped with P-type impurities (e.g., boron, gallium, or indium when the memory device 100 is fabricated on a substrate including silicon, for example). The impurity region SD1 may correspond to a source region or a drain region of the first PMOS transistor PM1, and the impurity region SD3 may correspond to a drain region or a source region of the first PMOS transistor PM1. The impurity region SD1 may be a region shared by two first PMOS transistors PM1 spaced apart in the second direction Y. A contact C_LA1 may be disposed on the impurity region SD1, and a contact C1 may be disposed on the impurity region SD3.

Similarly, within the active region PM21 of the second PMOS transistor PM2, impurity regions SD2, SD4 may be respectively disposed adjacent to a pair of sidewalls of the gate pattern PM22. The impurity regions SD2, SD4 and the gate pattern PM22 may constitute the second PMOS transistor PM2. The impurity regions SD2, SD4 may each be a high-concentration doping region doped with P-type impurities. The impurity region SD2 may correspond to a source region or a drain region of the second PMOS transistor PM2, and the impurity region SD4 may correspond to a drain region or a source region of the second PMOS transistor PM2. The impurity region SD2 may be a region shared by two second PMOS transistors PM2 spaced apart in the second direction Y. A contact C_LA2 may be disposed on the impurity region SD2, and a contact C3 may be disposed on the impurity region SD4.

In addition, an impurity region SD5 and a common impurity region SDC5 may be respectively disposed within the active region NM11 of the first NMOS transistor NM1. The impurity region SD5, the common impurity region SDC5, and the gate pattern NM12 may constitute the first NMOS transistor NM1. The impurity region SD5 and the common impurity region SDC5 may each be a high-concentration doping region doped with N-type impurities (e.g., phosphorous, arsenic, or antimony when the memory device 100 is fabricated on a substrate including silicon, for example). The impurity region SD5 may correspond to a source region or a drain region of the first NMOS transistor NM1, and the common impurity region SDC5 may correspond to a drain region or a source region of the first NMOS transistor NM1. The impurity region SD5 may be a region shared by two first NMOS transistors NM1 spaced apart in the second direction Y. The common impurity region SDC5 may be a region shared by the first NMOS transistor NM1 and the first offset transistor OC1. A contact C_LAB1 may be disposed on the impurity region SD5, and a common contact COC5 may be disposed on the common impurity region SDC5.

In addition, an impurity region SD6 and a common impurity region SDC6 may be respectively disposed within the active region NM21 of the second NMOS transistor NM2. The impurity region SD6, the common impurity region SDC6, and the gate pattern NM22 may constitute the second NMOS transistor NM2. The impurity region SD6 and the common impurity region SDC6 may each be a high-concentration doping region doped with N-type impurities. The impurity region SD6 may correspond to a source region or a drain region of the second NMOS transistor NM2, and the common impurity region SDC6 may correspond to a drain region or a source region of the second NMOS transistor NM2. The impurity region SD6 may be a region shared by two second NMOS transistors NM2 spaced apart in the second direction Y. The common impurity region SDC6 may be a region shared by the second NMOS transistor NM2 and the second offset transistor OC2. A contact C_LAB2 may be disposed on the impurity region SD6, and a common contact COC6 may be disposed on the common impurity region SDC6.

Within the active region OC11 shared by the first offset transistor OC1, the first isolation transistor ISO1, and the equalization transistor EQ, the common impurity region SDC5 and impurity regions SD7, SD8, SD9 may be respectively disposed. The common impurity region SDC5 and the impurity regions SD7, SD8, SD9 may each be a high-concentration doping region doped with N-type impurities.

The common impurity region SDC5 may correspond to a source region or a drain region of the first offset transistor OC1, and the impurity region SD7 may correspond to a drain region or a source region of the first offset transistor OC1. The impurity region SD7 may correspond to a source region or a drain region of the first isolation transistor ISO1, and the impurity region SD8 may correspond to a drain region or a source region of the first isolation transistor ISO1. The impurity region SD8 may correspond to a source region or a drain region of the equalization transistor EQ, and the impurity region SD9 may correspond to a drain region or a source region of the equalization transistor EQ.

The common impurity region SDC5 may be a region shared by the first offset transistor OC1 and the adjacent first NMOS transistor NM1. The impurity region SD7 may be a region shared by the first offset transistor OC1 and the first isolation transistor ISO1. The impurity region SD8 may be a region shared by the first isolation transistor ISO1 and the equalization transistor EQ.

The common contact COC5 may be disposed on the common impurity region SDC5, a contact C5 may be disposed on the impurity region SD7, a contact C6 may be disposed on the impurity region SD8, and a contact C7 may be disposed on the impurity region SD9.

Within the active region OC21 shared by the level balancing transistor LB, the second isolation transistor ISO2, and the second offset transistor OC2, impurity regions SD10, SD11, SD12 and the common impurity region SDC6 may be respectively disposed. The impurity regions SD10, SD11, SD12 and the common impurity region SDC6 may each be a high-concentration doping region doped with N-type impurities.

The impurity region SD10 may correspond to a source region or a drain region of the level balancing transistor LB, and the impurity region SD11 may correspond to a drain region or a source region of the level balancing transistor LB. The impurity region SD11 may correspond to a source region or a drain region of the second isolation transistor ISO2, and the impurity region SD12 may correspond to a drain region or a source region of the second isolation transistor ISO2. The impurity region SD12 may correspond to a source region or a drain region of the second offset transistor OC2, and the common impurity region SDC6 may correspond to a drain region or a source region of the second offset transistor OC2. In addition, the common impurity region SDC6 may correspond to a source region or a drain region of the second NMOS transistor NM2.

The impurity region SD11 may be a region shared by the level balancing transistor LB and the second isolation transistor ISO2. The impurity region SD12 may be a region shared by the second isolation transistor ISO2 and the second offset transistor OC2. The common impurity region SDC6 may be a region shared by the second offset transistor OC2 and the adjacent second NMOS transistor NM2.

A contact C8 may be disposed on the impurity region SD10, a contact C9 may be disposed on the impurity region SD11, the contact C10 may be disposed on the impurity region SD12, and the common contact COC6 may be disposed on the common impurity region SDC6.

In some embodiments, the common impurity region SDC5 may be disposed in a region including a boundary between the active region NM11 of the first NMOS transistor NM1 and the active region OC11 of the first offset transistor OC1, and the common impurity region SDC6 may be disposed in a region including a boundary between the active region NM21 of the second NMOS transistor NM2 and the active region OC21 of the second offset transistor OC2. In some embodiments, the common impurity region SDC5 may be disposed at the boundary between the active region NM11 of the first NMOS transistor NM1 and the active region OC11 of the first offset transistor OC1, and the common impurity region SDC6 may be disposed at the boundary between the active region NM21 of the second NMOS transistor NM2 and the active region OC21 of the second offset transistor OC2. At the boundary between the active region NM11 of the first NMOS transistor NM1 and the active region OC11 of the first offset transistor OC1, a width, in the second direction Y, of the active region NM11 may be different from a width, in the second direction Y, of the active region OC11.

In some embodiments, a gate contact G11 may be disposed on the gate pattern PM12 of the first PMOS transistor PM1, and a gate contact G21 may be disposed on the gate pattern PM22 of the second PMOS transistor PM2. Accordingly, in the embodiment shown in FIGS. 7 and 8, to configure two first PMOS transistors PM1 and two second PMOS transistors PM2, six contacts C1, C2, C3, C4, C_LA1, C_LA2 and four gate contacts G11, G12, G21, G22 may be disposed.

In some embodiments, a gate contact G31 may be disposed on the gate pattern NM12 of the first NMOS transistor NM1, and a gate contact G41 may be disposed on the gate pattern NM22 of the second NMOS transistor NM2.

According to the embodiment shown in FIGS. 7 and 8, an effective arrangement structure for securing an effective gate length of a gate pattern may be implemented through a structure where the first NMOS transistor NM1 and the first offset transistor OC1 share the common impurity region SDC5, and the second NMOS transistor NM2 and the second offset transistor OC2 share the common impurity region SDC6. Accordingly, characteristics of the first NMOS transistor NM1 and the second NMOS transistor NM2 may be improved. For example, control of leakage current (or off-current) of the transistor becomes easy, and mismatch between paired transistors may be improved (i.e., may be reduced) by securing uniformity as the effective gate length increases. Due to this, offset noise that may occur in the N-type sense amplifier may be effectively improved (i.e., may be reduced).

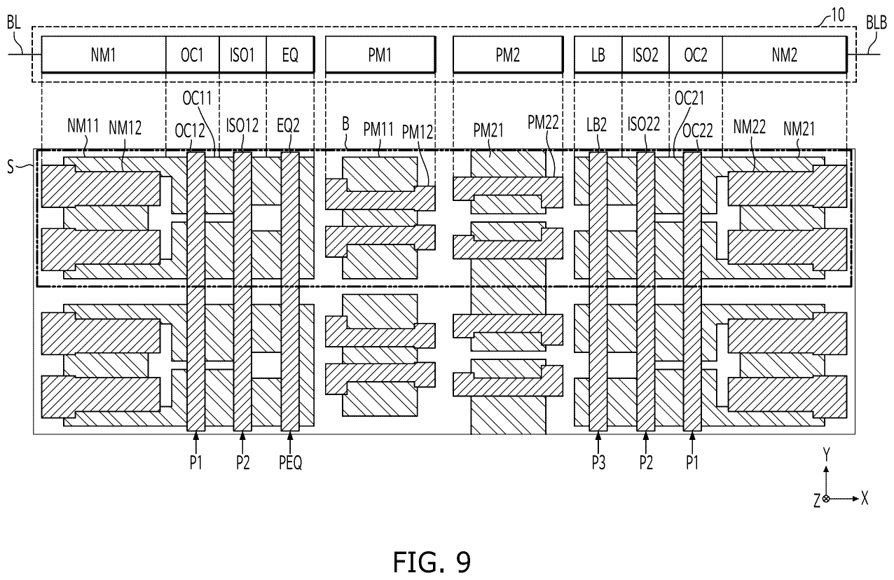

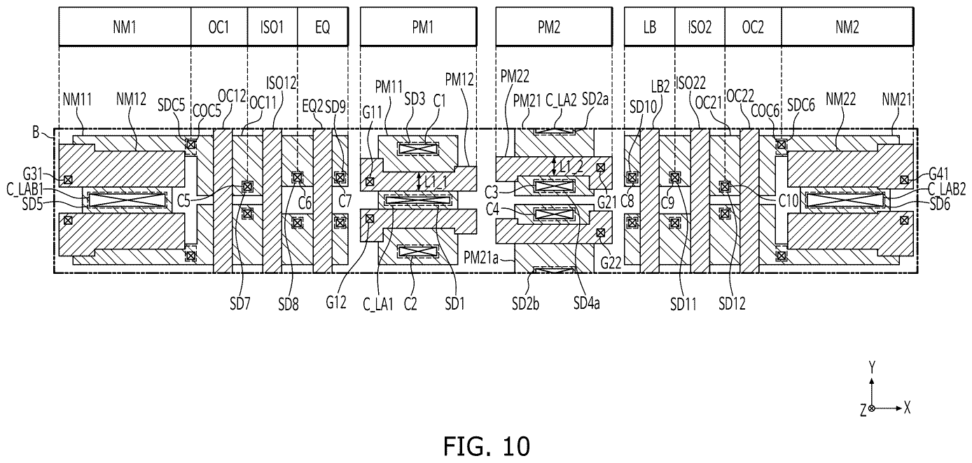

FIG. 9 is a diagram illustrating a layout of a bitline sense amplifier according to some embodiments of the present disclosure. FIG. 10 is an enlarged view of portion B of FIG. 9. Content already described in the description of FIGS. 7 and 8 will be briefly described or omitted, and differences from the embodiment shown in FIGS. 7 and 8 will be mainly described. FIGS. 9 and 10 will be described with reference to FIG. 5, except that the level balancing transistor LB is an N-type transistor.

Referring to FIGS. 9 and 10, based on two first PMOS transistors PM1 disposed spaced apart in the second direction Y and two second PMOS transistors PM2 disposed spaced apart in the second direction Y corresponding to the two first PMOS transistors PM1, the two first PMOS transistors PM1 may share the active region PM11, and the two second PMOS transistors PM2 may not share an active region PM21. That is, as shown in FIG. 10, the two first PMOS transistors PM1 may share the active region PM11, and each of the two second PMOS transistors PM2 may be formed in separated active regions PM21, PM21a.

In contrast, although not shown in FIG. 10, based on two first PMOS transistors PM1 disposed spaced apart in the second direction Y and two second PMOS transistors PM2 disposed spaced apart in the second direction Y corresponding to the two first PMOS transistors PM1, the two second PMOS transistors PM2 may share the active region PM21, and the two first PMOS transistors PM1 may not share the active region PM11. That is, based on the second direction Y, in a lower portion of the region shown in FIG. 10, the two second PMOS transistors PM2 may share the active region PM21a, and each of the two first PMOS transistors PM1 may be formed in separated active regions PM11 (not shown).

As described above, a form in which either a pair of two first PMOS transistors PM1 or a pair of two second PMOS transistors PM2 shares an active region may be repeatedly arranged along the second direction Y.

Referring to FIG. 10, a first active region, a second active region, and a third active region may be defined on a substrate (e.g., the substrate S of FIG. 9) included in a memory device. The first active region, the second active region, and the third active region may be regions formed by doping impurity ions on an upper side of the substrate S in the Z direction. The first active region may include the active region PM11 of the first PMOS transistor PM1 and the active regions PM21, PM21a of the second PMOS transistor PM2. The second active region may include an active region NM11 of the first NMOS transistor NM1 and an active region OC11 shared by the first offset transistor OC1, the first isolation transistor ISO1, and the equalization transistor EQ. The third active region may include an active region NM21 of the second NMOS transistor NM2 and an active region OC21 shared by the second offset transistor OC2, the second isolation transistor ISO2, and the level balancing transistor LB.

In some embodiments, a gate pattern PM12 of the first PMOS transistor PM1 and a gate pattern PM22 of the second PMOS transistor PM2 may each be formed in a rectangular pattern having a pair of sidewalls extending in a first direction X. In addition, a rectangular pattern extended by a predetermined length in a second direction Y may be formed from a portion of each of one of the pair of sidewalls of the gate pattern PM12 and one of the pair of sidewalls of the gate pattern PM22. At this time, a direction in which the extended rectangular pattern is formed from the gate pattern PM12 may be opposite to a direction in which the extended rectangular pattern is formed from the gate pattern PM22.

In some embodiments, the gate pattern PM12 of the first PMOS transistor PM1 and the gate pattern PM22 of the second PMOS transistor PM2 may each have an effective gate length L1_1, L1_2.

As described above, two first PMOS transistors PM1 may share the active region PM11 in the second direction Y, and two second PMOS transistors PM2 may have separated active regions PM21, PM21a. Although not shown, two second PMOS transistors PM2 may share the active region PM21a in the second direction Y, and two first PMOS transistors PM1 may each have separated active regions PM11, not shown. In addition, two gate patterns PM12 may be disposed spaced apart from each other in the second direction Y on the active region PM11, and each of gate patterns PM22 may be disposed spaced apart from each other in the second direction Y on each of the active regions PM21 and PM21a.

According to the layout arrangement, within the active region PM21 of the second PMOS transistor PM2, impurity regions SD2a, SD4a may be respectively disposed adjacent to a pair of sidewalls of the gate pattern PM22. Although not shown in the upper direction of the Y-axis, the impurity region SD2a may be a region shared by two second PMOS transistors PM2 spaced apart in the second direction Y. A contact C_LA2 may be disposed on the impurity region SD2a, and a contact C3 may be disposed on the impurity region SD4a.

In some embodiments, a gate contact G11 may be disposed on the gate pattern PM12 of the first PMOS transistor PM1, and a gate contact G21 may be disposed on the gate pattern PM22 of the second PMOS transistor PM2. Accordingly, in the embodiment shown in FIGS. 9 and 10, to configure two first PMOS transistors PM1 and two second PMOS transistors PM2, six contacts C1, C2, C3, C4, C_LA1, C_LA2 and four gate contacts G11, G12, G21, G22 may be disposed. The contact C_LA2 in the second PMOS transistor PM2 is shown as only half on the impurity region SD2a, but the other half is shown on the impurity region SD2b, so it can be understood that one unit contact is disposed.

According to the embodiment shown in FIGS. 9 and 10, compared to the embodiment shown in FIGS. 7 and 8, there is an advantage that multiple layers do not need to be configured to implement a lead wire (i.e., an interconnection pattern) for connecting the gate contact G11 of the first PMOS transistor PM1 and the contact C3 of the second PMOS transistor PM2, and a lead wire for connecting the gate contact G21 of the second PMOS transistor PM2 and a contact C1 of the first PMOS transistor PM1. Through such a configuration, the design for implementing the bitline sense amplifier 10 of the memory device may be simplified. In addition, by configuring a single layer, the integration density of the memory device may be improved. In an embodiment, the active region PM21 may be shifted in the second direction Y relative to the active region PM11, while the gate pattern PM22 remains in the same places, as shown in FIGS. 7 and 8.

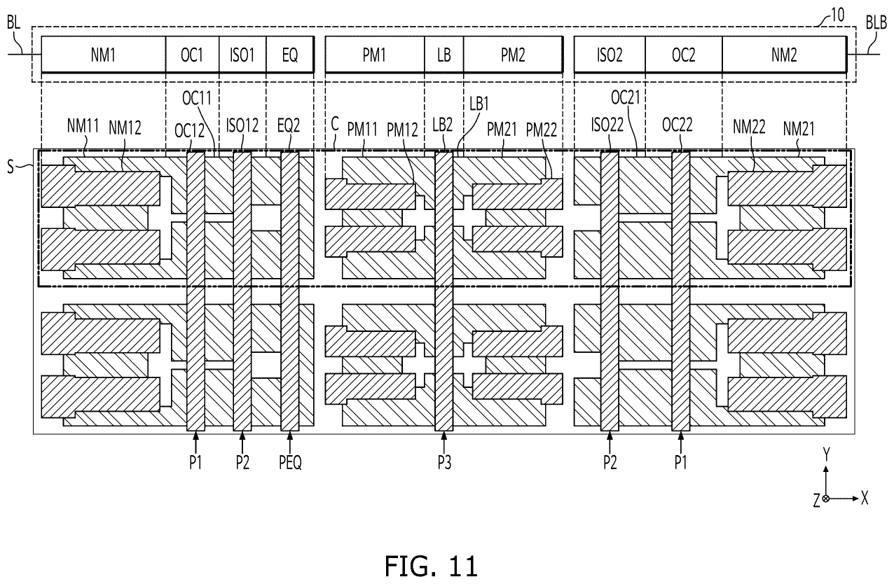

FIG. 11 is a diagram illustrating a layout of a bitline sense amplifier according to some embodiments of the present disclosure. FIG. 12 is an enlarged view of portion C of FIG. 11. In FIG. 11, content already described in the description of FIGS. 7 to 10 will be briefly described or omitted, and differences from the embodiment shown in FIGS. 7 to 10 will be mainly described. FIGS. 11 and 12 will be described with reference to FIG. 5 in which the level balancing transistor LB is a P-type transistor.

Referring to FIG. 11, compared to the embodiment shown in FIGS. 7 and 8, the level balancing transistor LB may share a common impurity region with a P-type sense amplifier. For example, the level balancing transistor LB is disposed between a first PMOS transistor PM1 and the second PMOS transistor PM2, and may share a common impurity region (e.g., the common impurity regions SDC1, SDC2 of FIG. 12) with the first PMOS transistor PM1, and may share a common impurity region (e.g., the common impurity regions SDC3, SDC4 of FIG. 12) with the second PMOS transistor PM2. That is, FIG. 11 shows a layout where the first PMOS transistor PM1, the level balancing transistor LB, and the second PMOS transistor PM2 are sequentially arranged along the first direction X, and four sets of these transistors are arranged in the second direction Y. In addition, the first PMOS transistor PM1 and the level balancing transistor LB that are adjacent in the first direction X may share a common impurity region, and the second PMOS transistor PM2 and the level balancing transistor LB that are adjacent in the first direction X may share a common impurity region.

Referring to FIG. 12, two first PMOS transistors PM1, PM3, two second PMOS transistors PM2, PM4, and two level balancing transistors LB_1, LB_2, which are disposed spaced apart from each other in the second direction Y, are shown. In addition, two first NMOS transistors NM1, two second NMOS transistors NM2, two first offset transistors OC1, two second offset transistors OC2, two first isolation transistors ISO1, two second isolation transistors ISO2, and two equalization transistors EQ, which are disposed spaced apart from each other in the second direction Y, are shown.

A first active region, a second active region, and a third active region may be defined on a substrate (e.g., the substrate S of FIG. 11) included in a memory device. Here, considering that FIG. 12 is a layout of a bitline sense amplifier, that is, a top view of a bitline sense amplifier, the substrate S may be disposed below the components of FIG. 12 in the Z-axis direction.

The first active region, the second active region, and the third active region may be regions formed by doping impurity ions on an upper side of the substrate S. The first active region may include active regions PM11, PM31 of first PMOS transistors PM1, PM3, active regions PM21, PM41 of second PMOS transistors PM2, PM4, and connected active regions LB1, LB1a of the level balancing transistors LB_1, LB_2. The second active region may include an active region NM11 of the first NMOS transistor NM1 and an active region OC11 shared by the first offset transistor OC1, the first isolation transistor ISO1, and the equalization transistor EQ. The third active region may include an active region NM21 of the second NMOS transistor NM2 and an active region OC21 shared by the second offset transistor OC2 and the second isolation transistor ISO2.

In some embodiments, the level balancing transistors LB_1, LB_2 may include a gate pattern LB2 including a pair of sidewalls SW1, SW2 extending in the second direction Y on connected active regions LB1, LB1a. The common impurity regions SDC1, SDC2 shared with first PMOS transistors PM1, PM3 are disposed adjacent to one sidewall SW1 of the gate pattern LB2, and the common impurity regions SDC3, SDC4 shared with second PMOS transistors PM2, PM4 may be disposed adjacent to the other sidewall SW2 of the gate pattern LB2.

In some embodiments, the common impurity regions SDC1, SDC2 are disposed in a region including a boundary between active regions PM11, PM31 of first PMOS transistors PM1, PM3 and connected active regions LB1, LB1a of the level balancing transistors LB_1, LB_2, and the common impurity regions SDC3, SDC4 may be disposed in a region including a boundary between active regions PM21, PM41 of second PMOS transistors PM2, PM4 and the connected active regions LB1, LB1a of the level balancing transistors LB_1, LB_2. In some embodiments, the common impurity regions SDC1, SDC2 are disposed at the boundary between active regions PM11, PM31 of first PMOS transistors PM1, PM3 and connected active regions LB1, LB1a of the level balancing transistors LB_1, LB_2, and the common impurity regions SDC3, SDC4 may be disposed at the boundary between active regions PM21, PM41 of second PMOS transistors PM2, PM4 and the connected active regions LB1, LB1a of the level balancing transistors LB_1, LB_2. At the boundary between the active regions PM11, PM31 of first PMOS transistors PM1, PM3 and the connected active regions LB1, LB1a of the level balancing transistors LB_1, LB_2, widths, in the second direction Y, of the active regions PM11, PM31 may be different from widths, in the second direction, of the connected active regions LB1, LB1a. At the boundary between the active regions PM21, PM41 of second PMOS transistors PM2, PM4 and the connected active regions LB1, LB1a of the level balancing transistors LB_1, LB_2, widths, in the second direction Y, of the active regions PM21, PM41 may be different from widths, in the second direction Y, of the connected active regions LB1, LB1a.

In some embodiments, a gate pattern PM12 of the first PMOS transistor PM1 is disposed on an active region PM11 and may include a rectangular main region MR1 including a pair of long sidewalls LSW11, LSW12 extending in the first direction X and a pair of short sidewalls SSW11, SSW12 extending in the second direction Y, and a rectangular extended region ER1 extending in the second direction Y from one long sidewall LSW11 of the gate pattern PM12. An impurity region SD1 is disposed adjacent to the other long sidewall LSW12 of the gate pattern PM12, and the common impurity region SDC1 may be disposed adjacent to one short sidewall SSW11 of the gate pattern PM12. Accordingly, one short sidewall SSW11 of the gate pattern PM12 may be disposed adjacent to one sidewall SW1 of the gate pattern LB2.

In some embodiments, a gate pattern PM22 of the second PMOS transistor PM2 is disposed on an active region PM21 and may include a rectangular main region MR2 including a pair of long sidewalls LSW21, LSW22 extending in the first direction X and a pair of short sidewalls SSW21, SSW22 extending in the second direction Y, and a rectangular extended region ER2 extending in the second direction Y from one long sidewall LSW21 of the gate pattern PM22. An impurity region SD2 is disposed adjacent to the other long sidewall LSW22 of the gate pattern PM22, and a common impurity region SDC3 may be disposed adjacent to one short sidewall SSW21 of the gate pattern PM22. Accordingly, one short sidewall SSW21 of the gate pattern PM22 may be disposed adjacent to the other sidewall SW2 of the gate pattern LB2.

In some embodiments, the gate pattern PM12 of the first PMOS transistor PM1 and the gate pattern PM22 of the second PMOS transistor PM2 may each have an effective gate length L2_1, L2_2. Here, since the first PMOS transistor PM1 and the second PMOS transistor PM2 have a structure sharing the common impurity regions SDC1, SDC3 with the level balancing transistor LB_1, assuming that the above structures are formed using the same area as the other embodiments, the effective gate lengths L2_1, L2_2 of each of the gate patterns PM12, PM22 shown in FIGS. 11 and 12 may have values increased compared to the effective gate lengths L1_1, L1_2 of each of the gate patterns PM12, PM22 shown in FIGS. 7 to 10. Through this configuration, characteristics of the first PMOS transistor PM1 and the second PMOS transistor PM2 included in the bitline sense amplifier 10 may be improved.

In some embodiments, a gate pattern PM32 of a first PMOS transistor PM3 disposed below the first PMOS transistor PM1 in the second direction Y is disposed adjacent to the other long sidewall LSW12 of the gate pattern PM12, and a gate pattern PM42 of a second PMOS transistor PM4 disposed below the second PMOS transistor PM2 in the second direction Y may be disposed adjacent to the other long sidewall LSW22 of the gate pattern PM22.

In some embodiments, a contact C_LA1 may be disposed on an impurity region SD1, and a contact C_LA2 may be disposed on an impurity region SD2. In addition, common contacts COC1, COC2, COC3, COC4 may be respectively disposed on the common impurity regions SDC1, SDC2, SDC3, SDC4. The impurity regions SD1, SD2 and the common impurity regions SDC1, SDC2, SDC3, SDC4 may each be a high-concentration doping region doped with P-type impurities.

In some embodiments, gate contacts G11, G12 may be respectively disposed on gate patterns PM12, PM32 of first PMOS transistors PM1, PM3, and gate contacts G21, G22 may be respectively disposed on gate patterns PM22, PM42 of second PMOS transistors PM2, PM4. Accordingly, in the embodiment shown in FIGS. 11 and 12, to configure two first PMOS transistors PM1, PM3, two second PMOS transistors PM2, PM4, and two level balancing transistors LB_1, LB_2, six contacts COC1, COC2, COC3, COC4, C_LA1, C_LA2 and four gate contacts G11, G12, G21, G22 may be disposed.

According to the embodiment shown in FIGS. 11 and 12, compared to the embodiment shown in FIGS. 7 to 10, the number of contacts included in the bitline sense amplifier 10 may be effectively reduced. Due to this, the design for implementing the bitline sense amplifier 10 of the memory device may be simplified. In addition, by reducing the number of contacts, the integration density of the memory device may be improved.

According to the embodiment shown in FIGS. 11 and 12, a contact (e.g., the common contact COC1, COC3 of FIG. 12) disposed adjacent to the one long sidewall LSW11 of the gate pattern PM12 or the one long sidewall LSW21 of the gate pattern PM22 is disposed in a different position from a contact (e.g., the contact C1, C3 of FIG. 8) disposed adjacent to one long sidewall of the gate pattern PM12 or one long sidewall of the gate pattern PM22 according to the embodiment shown in FIGS. 7 and 8, thereby implementing an effective arrangement structure for securing an effective gate length of the gate pattern. Due to this, the effective gate lengths L2_1, L2_2 of each of the gate patterns PM12, PM22 shown in FIGS. 11 and 12 may have increased values. Accordingly, characteristics of the first PMOS transistor PM1 and the second PMOS transistor PM2 may be improved. For example, control of leakage current (or off-current) of the transistor becomes easy, and mismatch between paired transistors may be improved by securing uniformity as the effective gate length increases. Due to this, offset noise that may occur in the P-type sense amplifier may be effectively improved.

In addition, the number of contacts included in the bitline sense amplifier 10 of the memory device may be effectively reduced by optimizing the arrangement structure of transistors. Due to this, a region occupied by the contacts may be secured, and the gate pattern length of the transistors may be increased, thereby effectively improving electrical characteristics of the transistors, for example, leakage current control or mismatch between transistors.

In addition, since some process steps related to contact formation may be simplified or reduced, mismatch between transistors due to process variations may be effectively improved. Furthermore, since more free space is secured within the same area due to the reduction in the number of contacts, the integration density of the entire memory device may also be improved.

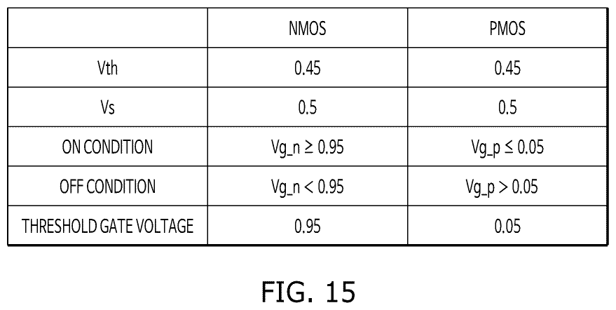

In addition, since the level balancing transistors LB_1, LB_2 are implemented as PMOS transistors, the level balancing control signal P3 may be stably driven at a relatively low voltage, thereby providing a structure advantageous for low-voltage design of the entire circuit. The description for this will be described in detail later with reference to FIG. 15.

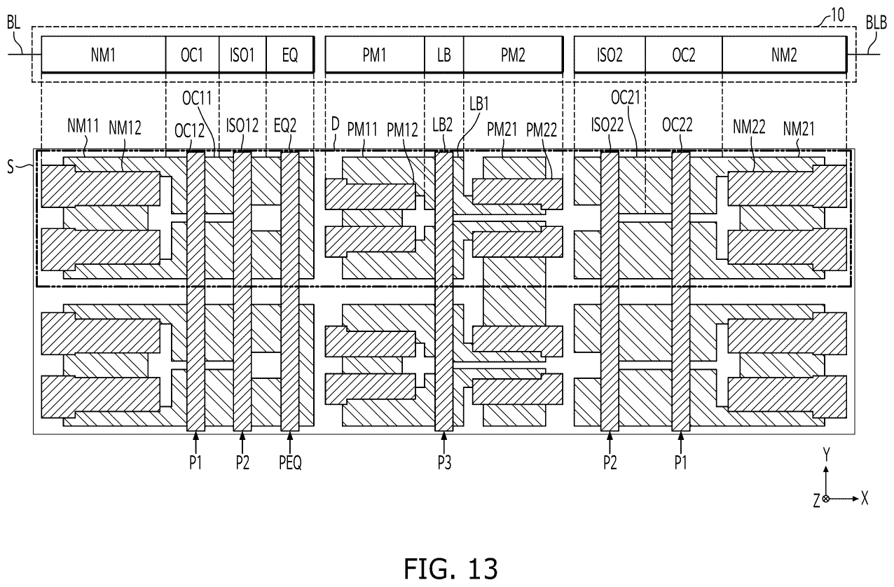

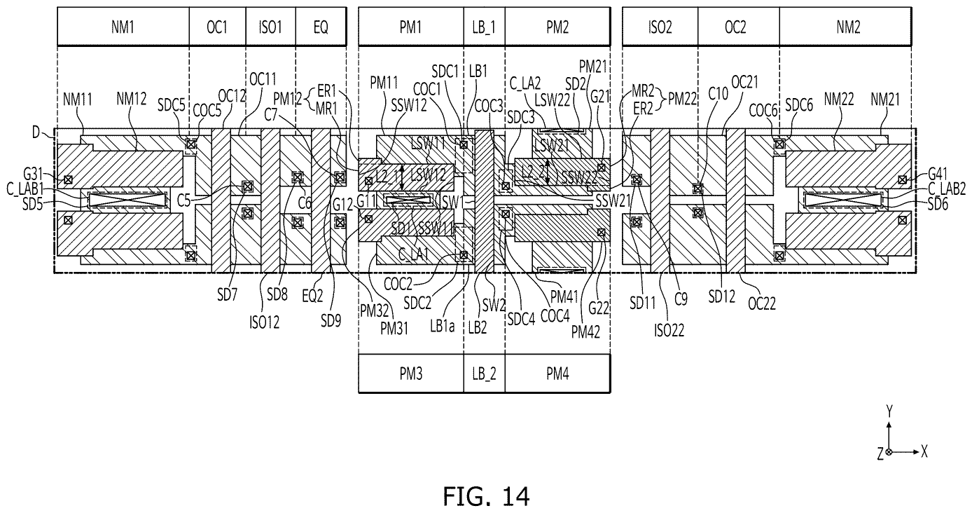

FIG. 13 is a diagram illustrating a layout of a bitline sense amplifier according to some embodiments of the present disclosure. FIG. 14 is an enlarged view of portion D of FIG. 13. Content already described in the description of FIGS. 7 to 12 will be briefly described or omitted, and differences from the embodiment shown in FIGS. 7 to 12 will be mainly described. FIGS. 13 and 14 will be described with reference to FIG. 5 in which the level balancing transistor LB is a P-type transistor.

Referring to FIGS. 13 and 14, as in the embodiment shown in FIGS. 9 and 10, based on two first PMOS transistors PM1, PM3 disposed spaced apart in the second direction Y and two second PMOS transistors PM2, PM4 disposed spaced apart in the second direction Y corresponding to the two first PMOS transistors PM1, PM3, the two first PMOS transistors PM1, PM3 may share active regions PM11, PM31, and the two second PMOS transistors PM2, PM4 may not share active regions PM21, PM41. That is, the two first PMOS transistors PM1, PM3 may share active regions PM11, PM31, and each of the two second PMOS transistors PM2, PM4 may be formed in separated active regions PM21, PM41. In contrast, although not shown, the two second PMOS transistors PM2, PM4 may share active regions PM21, PM41, and each of the two first PMOS transistors PM1, PM3 may be formed in separated active regions PM11, PM31. Accordingly, as shown in FIG. 13, a form in which either a pair of two first PMOS transistors PM1, PM3 or a pair of two second PMOS transistors PM2, PM4 shares an active region may be repeatedly arranged along the second direction Y.

In addition, referring to FIG. 13, as in the embodiment shown in FIGS. 11 and 12, the level balancing transistor LB may share a common impurity region with a P-type sense amplifier.

Referring to FIG. 14, two first PMOS transistors PM1, PM3, two second PMOS transistors PM2, PM4, and two level balancing transistors LB_1, LB_2, which are disposed spaced apart from each other in the second direction Y, are shown. In addition, two first NMOS transistors NM1, two second NMOS transistors NM2, two first offset transistors OC1, two second offset transistors OC2, two first isolation transistors ISO1, two second isolation transistors ISO2, and two equalization transistors EQ, which are disposed spaced apart from each other in the second direction Y, are shown.

A first active region, a second active region, and a third active region may be defined on a substrate (e.g., the substrate S of FIG. 13) included in a memory device. The first active region may include active regions PM11, PM31 of first PMOS transistors PM1, PM3, active regions PM21, PM41 of second PMOS transistors PM2, PM4, and connected active regions LB1, LB1a of the level balancing transistors LB_1, LB_2. The second active region may include an active region NM11 of the first NMOS transistor NM1 and an active region OC11 shared by the first offset transistor OC1, the first isolation transistor ISO1, and the equalization transistor EQ. The third active region may include an active region NM21 of the second NMOS transistor NM2 and an active region OC21 shared by the second offset transistor OC2 and the second isolation transistor ISO2.

In some embodiments, a gate pattern PM12 of the first PMOS transistor PM1 is disposed on an active region PM11 and may include a rectangular main region MR1 including a pair of long sidewalls LSW11, LSW12 extending in the first direction X and a pair of short sidewalls SSW11, SSW12 extending in the second direction Y, and a rectangular extended region ER1 extending in the second direction Y from one long sidewall LSW11 of the gate pattern PM12. An impurity region SD1 is disposed adjacent to the other long sidewall LSW12 of the gate pattern PM12, and a common impurity region SDC1 may be disposed adjacent to one short sidewall SSW11 of the gate pattern PM12. Accordingly, the one short sidewall SSW11 of the gate pattern PM12 may be disposed adjacent to one sidewall SW1 of the gate pattern LB2.

In some embodiments, a gate pattern PM22 of the second PMOS transistor PM2 is disposed on an active region PM21 and may include a rectangular main region MR2 including a pair of long sidewalls LSW21, LSW22 extending in the first direction X and a pair of short sidewalls SSW21, SSW22 extending in the second direction Y, and a rectangular extended region ER2 extending in the second direction Y from one long sidewall LSW21 of the gate pattern PM22. An impurity region SD2 is disposed adjacent to the other long sidewall LSW22 of the gate pattern PM22, and a common impurity region SDC3 may be disposed adjacent to one short sidewall SSW21 of the gate pattern PM22. Accordingly, one short sidewall SSW21 of the gate pattern PM22 may be disposed adjacent to the other sidewall SW2 of the gate pattern LB2.

In some embodiments, as shown in FIG. 14, a common impurity region SDC1 and an impurity region SD1, a common impurity region SDC2 and an impurity region SD1, or a common impurity region SDC3 and an impurity region SD2 may be respectively disposed spaced apart from each other based on gate patterns PM12, PM32, PM22. For example, since the common impurity region SDC1 is disposed relatively upward based on the gate pattern PM12, the impurity region SD1 may be disposed relatively downward based on the gate pattern PM12. However, the scope of the present disclosure is not limited thereto.

In some embodiments, the gate pattern PM12 of the first PMOS transistor PM1 and the gate pattern PM22 of the second PMOS transistor PM2 may each have an effective gate length L2_1, L2_2. Here, since the first PMOS transistor PM1 and the second PMOS transistor PM2 have a structure sharing common impurity regions SDC1, SDC3 with a level balancing transistor LB_1, assuming that the above structures are formed using the same area as the other embodiments, the effective gate lengths L2_1, L2_2 of each of the gate patterns PM12, PM22 shown in FIGS. 13 and 14 may have values increased compared to the effective gate lengths L1_1, L1_2 of the gate patterns PM12, PM22 shown in FIGS. 7 to 10. Through this configuration, characteristics of the first PMOS transistor PM1 and the second PMOS transistor PM2 included in the bitline sense amplifier 10, for example, leakage current control or mismatch characteristics between transistors, may be improved.

In some embodiments, unlike the embodiment shown in FIGS. 11 and 12, a gate pattern PM32 of a first PMOS transistor PM3 disposed below the first PMOS transistor PM1 in the second direction Y is disposed adjacent to the other long sidewall LSW12 of the gate pattern PM12, and a gate pattern PM42 of a second PMOS transistor PM4 disposed below the second PMOS transistor PM2 in the second direction Y may be disposed adjacent to the one long sidewall LSW21 of the gate pattern PM22.

According to the embodiment shown in FIGS. 13 and 14, to configure two first PMOS transistors PM1, PM3, two second PMOS transistors PM2, PM4, and two level balancing transistors LB_1, LB_2, six contacts COC1, COC2, COC3, COC4, C_LA1, C_LA2 and four gate contacts G11, G12, G21, G22 may be disposed. Accordingly, compared to the embodiment shown in FIGS. 7 to 10, the number of contacts included in the bitline sense amplifier 10 may be effectively reduced. Due to this, an effective arrangement structure for securing an effective gate length of a transistor included in a P-type sense amplifier is provided, and electrical characteristics of the transistor, for example, leakage current control or mismatch between transistors, may be effectively improved. In addition, since some process steps related to contact formation may be simplified or reduced, mismatch between transistors due to process variations may be effectively improved, or integration density of a memory device may be improved.

According to the embodiment shown in FIGS. 13 and 14, a contact (e.g., the common contact COC1, COC3 of FIG. 14) disposed adjacent to the one long sidewall LSW11 of the gate pattern PM12 or the one long sidewall LSW21 of the gate pattern PM22 is disposed in a different position from a contact (e.g., the contact C1, C3 of FIG. 10) disposed adjacent to one long sidewall of the gate pattern PM12 or one long sidewall of the gate pattern PM22 according to the embodiment shown in FIGS. 9 and 10, thereby implementing an effective arrangement structure for securing an effective gate length of the gate pattern. Due to this, the effective gate lengths L2_1, L2_2 of the gate patterns PM12, PM22 shown in FIGS. 13 and 14 may have increased values. Accordingly, characteristics of the first PMOS transistor PM1 and the second PMOS transistor PM2, for example, leakage current control or mismatch characteristics between transistors, may be improved, and offset noise that may occur in the P-type sense amplifier may be effectively improved.

According to the embodiment shown in FIGS. 13 and 14, since the level balancing transistors LB_1, LB_2 are implemented as PMOS transistors, the level balancing control signal P3 may be stably driven at a relatively low voltage, thereby providing a structure advantageous for low-voltage design of the entire circuit.

According to the embodiment shown in FIGS. 13 and 14, compared to the embodiment shown in FIGS. 11 and 12, there is an advantage that multiple layers do not need to be configured to implement a lead wire for connecting a gate contact G11 of the first PMOS transistor PM1 and a common contact COC3 of the second PMOS transistor PM2, and a lead wire for connecting a gate contact G21 of the second PMOS transistor PM2 and a common contact COC1 of the first PMOS transistor PM1. Through such a configuration, the design for implementing the bitline sense amplifier 10 of the memory device may be simplified. In addition, by configuring a single layer, the integration density of the memory device may be improved.

Meanwhile, the layouts of the bitline sense amplifier 10 shown in FIGS. 7 to 14 are merely an example of the present disclosure, and the arrangement, shape, size, array, etc., of the active regions, gate patterns, impurity regions, and contacts described above may be variously changed within the technical idea of the present disclosure. For example, the shape of the illustrated gate pattern, the extension direction, the extension position from the main region, etc., may be implemented in various ways according to circuit design conditions or process constraints.

FIG. 15 is a diagram illustrating differences according to a design of a level balancing transistor according to some embodiments of the present disclosure.

In some embodiments, a level balancing transistor (e.g., the level balancing transistor LB of FIG. 5) may be implemented as a PMOS transistor. In this case, the level balancing transistor may be disposed between a first PMOS transistor and a second PMOS transistor, as shown in FIGS. 11 to 14. Additionally or alternatively, the level balancing transistor may be implemented as an NMOS transistor. In this case, the level balancing transistor may be disposed between a second PMOS transistor and a second NMOS transistor, as shown in FIGS. 7 to 10.

Referring to FIG. 15, a difference in threshold gate voltage when a level balancing transistor is implemented as an NMOS transistor or a PMOS transistor is shown. For example, it is assumed that an NMOS transistor and a PMOS transistor each have the same threshold voltage (e.g., 0.45V), and the same voltage (e.g., 0.5V) is applied to a source terminal. At this time, in the case of the NMOS transistor, a condition for the transistor to be turned on may be that a voltage of a gate terminal is greater than or equal to 0.95V, and a condition for the transistor to be turned off may be that the voltage of the gate terminal is less than 0.95V. That is, it can be seen that a threshold gate voltage for determining turn-on or turn-off of the transistor is 0.95V. In contrast, in the case of the PMOS transistor, a condition for the transistor to be turned on may be that a voltage of a gate terminal is less than or equal to 0.05V, and a condition for the transistor to be turned off may be that the voltage of the gate terminal is greater than 0.05V. That is, it can be seen that a threshold gate voltage for determining turn-on or turn-off of the transistor is 0.05V. As such, the threshold gate voltage may be effectively reduced when the level balancing transistor is implemented as a PMOS transistor. Therefore, in some embodiments, since the level balancing transistor is implemented as a PMOS transistor, a level balancing control signal may be stably driven at a relatively low voltage, thereby providing a structure advantageous for low-voltage design of the entire circuit.

Meanwhile, the threshold voltage, source voltage, threshold gate voltage, etc., of the NMOS transistor and PMOS transistor shown in FIG. 15 are exemplary for the purpose of explanation, and the scope of the present disclosure is not limited thereto.

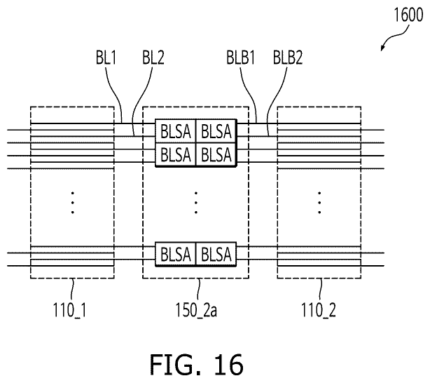

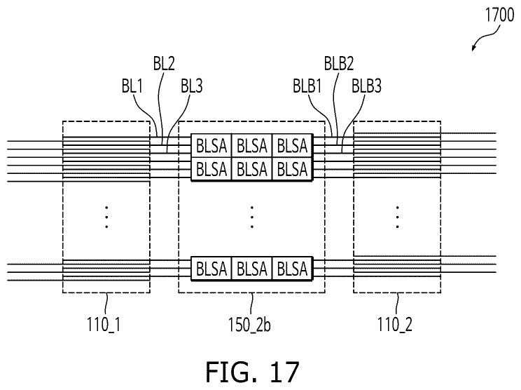

FIGS. 16 and 17 are diagrams illustrating a memory device to which a bitline sense amplifier is applied according to some embodiments of the present disclosure.

A memory device 1600 shown in FIG. 16 and a memory device 1700 shown in FIG. 17 may each correspond to the memory device 100 described in FIG. 4. A first memory cell array 110_1 and a second memory cell array 110_2 included in each of the memory device 1600 of FIG. 16 and the memory device 1700 of FIG. 17 may correspond to the first memory cell array 110_1 and the second memory cell array 110_2 included in the memory device 100 of FIG. 4. In addition, sense amplifiers 150_2a, 150_2b included in each of the memory device 1600 of FIG. 16 and the memory device 1700 of FIG. 17 may correspond to the sense amplifier 150_2 included in the memory device 100 of FIG. 4. Bitline sense amplifiers BLSA included in each of the sense amplifiers 150_2a, 150_2b may be implemented as the bitline sense amplifier described in FIGS. 5 to 15.

The memory device 1600 of FIG. 16, unlike the memory device 100 of FIG. 4, may have two bitline sense amplifiers BLSA disposed adjacent to each other within a sense amplifier 150_2a. The two bitline sense amplifiers BLSA may be connected to first and second bitlines BL1, BL2 and first and second complementary bitlines BLB1, BLB2. One of the two bitline sense amplifiers BLSA may sense a voltage change of a first bitline pair BL1, BLB1, and the other of the two bitline sense amplifiers BLSA may sense a voltage change of a second bitline pair BL2, BLB2.

The memory device 1700 of FIG. 17, unlike the memory device 100 of FIG. 4, may have three bitline sense amplifiers BLSA disposed adjacent to each other within a sense amplifier 150_2b. The three bitline sense amplifiers BLSA may be connected to first to third bitlines BL1, BL2, BL3 and first to third complementary bitlines BLB1, BLB2, BLB3. Each of the three bitline sense amplifiers BLSA may sense a voltage change of each of first to third bitline pairs (BL1, BLB1), (BL2, BLB2), (BL3, BLB3).

The memory devices 1600, 1700 of FIGS. 16 and 17 may be selectively applied according to a trend where a size of a unit cell decreases due to miniaturization of design rules according to high integration of memory cell devices. According to an embodiment, n bitline sense amplifiers BLSA are disposed adjacent to each other, the n bitline sense amplifiers BLSA are connected to first to n-th bitlines and first to n-th complementary bitlines, and each of the n bitline sense amplifiers BLSA may sense a voltage change of each of first to n-th bitline pairs. Here, n may be a natural number greater than or equal to 2.

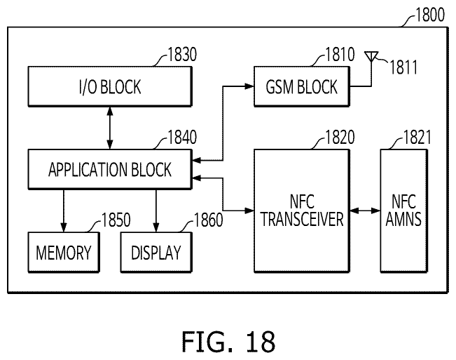

FIG. 18 is a diagram illustrating an example where a memory device including a bitline sense amplifier according to some embodiments of the present disclosure is applied to a mobile device. Here, the mobile device may be a mobile phone or a smart phone.

Referring to FIG. 18, a mobile device 1800 may include a GSM (Global System for Mobile communication) block 1810, an NFC (Near Field Communication) transceiver 1820, an input/output block 1830, an application block 1840, a memory 1850, and a display 1860. In FIG. 18, components/blocks of the mobile device 1800 are shown by way of example. Accordingly, the mobile device 1800 may further include additional components/blocks in addition to the illustrated components/blocks. In addition, although the present embodiment is shown as using GSM technology, the mobile device 1800 may be implemented based on other technologies such as CDMA (Code Division Multiple Access). The blocks of FIG. 18 may be implemented in an integrated circuit form. Alternatively, some of the blocks may be implemented in an integrated circuit form, and some of the blocks may be implemented in separate forms.

A GSM block 1810 is connected to an antenna 1811 and may operate to provide wireless phone operation in a known manner. The GSM block 1810 internally includes a receiver and a transmitter and may perform corresponding receiving and transmitting operations.

An NFC transceiver 1820 may be configured to transmit and receive NFC signals using inductive coupling for wireless communication. The NFC transceiver 1820 provides NFC signals to an NFC antenna matching network system 1821, and the NFC antenna matching network system 1821 may transmit NFC signals through inductive coupling. The NFC antenna matching network system 1821 receives NFC signals provided from other NFC devices and may provide the received NFC signals to the NFC transceiver 1820.

An application block 1840 includes hardware circuits, for example, one or more processors, and may operate to provide various user applications provided by a mobile device 1800. User applications may include voice call operations, data transfer, data swap, and the like. The application block 1840 may operate with the GSM block 1810 and/or the NFC transceiver 1820 to provide operational features of the GSM block 1810 and/or the NFC transceiver 1820. Alternatively, the application block 1840 may include a program for mobile point of sales (POS). Such a program may provide credit card purchase and payment functions using a mobile phone, that is, a smart phone.

A display 1860 may display an image in response to display signals received from an application block 1840. The image may be provided by the application block 1840 or generated by a camera embedded in a mobile device 1800. The display 1860 internally includes a frame buffer for temporary storage of pixel values and may be configured as a liquid crystal display screen with associated control circuits. The present disclosure is not limited thereto. In an embodiment, the display 1860 may be implemented using an organic light-emitting diode display, a quantum dot display, or a microLED display.

An input/output block 1830 provides input functions to a user and may provide outputs to be received through an application block 1840.

A memory 1850 stores programs (instructions) and/or data to be used by an application block 1840 and may be implemented as RAM, ROM, flash memory, or the like. Accordingly, the memory 1850 may include not only volatile but also non-volatile storage elements. For example, the memory 1850 may correspond to the memory devices 100, 1600, 1700 described in FIGS. 1 to 17.

In some embodiments, the memory 1850 may include the bitline sense amplifier described in FIGS. 1 to 17. The bitline sense amplifier may include an N-type sense amplifier connected to a bitline and a complementary bitline, a P-type sense amplifier connected to the N-type sense amplifier through a sensing bitline and a complementary sensing bitline, and a level balancing transistor connecting the sensing bitline and the complementary sensing bitline based on a level balancing control signal. The level balancing transistor may share a common impurity region with the P-type sense amplifier.

Although the present disclosure has been described with reference to the embodiments shown in the drawings, this is merely exemplary, and those skilled in the art will understand that various modifications and equivalent other embodiments are possible therefrom within the technical idea of the present disclosure. Therefore, the true technical protection scope of the present disclosure should be determined by the technical idea of the appended claims.

1. A memory device comprising a bitline sense amplifier sensing a voltage difference between a bitline and a complementary bitline, the bitline sense amplifier comprising:
an N-type sense amplifier connected to the bitline and the complementary bitline;
a P-type sense amplifier including a first PMOS transistor having a first impurity region as one of a pair of source/drain regions of the first PMOS transistor and connected to the N-type sense amplifier through a first sensing bitline and a first complementary sensing bitline; and
a level balancing transistor including a first impurity region as one of a pair of source/drain regions of the level balancing transistor and connecting the first sensing bitline and the first complementary sensing bitline based on a level balancing control signal,
wherein the first impurity region of the level balancing transistor and the first impurity region of the first PMOS transistor are a first common impurity region shared between the level balancing transistor and the first PMOS transistor.

2. The memory device as claimed in claim 1,
wherein the P-type sense amplifier further comprises a second PMOS transistor,
wherein the first PMOS transistor has a first gate electrode pattern connected to the first sensing bitline,
wherein the second PMOS transistor has a second gate electrode pattern connected to the first complementary sensing bitline, and
wherein the level balancing transistor is a PMOS transistor and, when viewed in a plan view, is disposed in a space between the first PMOS transistor and the second PMOS transistor.

3. The memory device as claimed in claim 2, further comprising:
a substrate on which an active region is defined,
wherein the active region comprises a first PMOS active region, a second PMOS active region, and a connected active region disposed between the first PMOS active region and the second PMOS active region,
wherein the connected active region is connected to the first PMOS active region and the second PMOS active region,
wherein the first PMOS transistor is disposed on the first PMOS active region,
wherein the second PMOS transistor is disposed on the second PMOS active region, and
wherein the level balancing transistor is disposed on the connected active region.

4. The memory device as claimed in claim 3,
wherein the level balancing transistor further comprises:
a level balancing gate electrode pattern disposed on the connected active region and comprising a pair of sidewalls spaced apart in a first direction parallel to an upper surface of the substrate and extending in a second direction parallel to the upper surface of the substrate and intersecting the first direction; and
a second impurity region as the other of the pair of source/drain regions of the level balancing transistor,
wherein the second impurity region of the level balancing transistor and a first impurity region of the second PMOS transistor are a second common impurity region shared between the level balancing transistor and the second PMOS transistor,
wherein the first impurity region of the second PMOS transistor is one of a pair of source/drain regions of the second PMOS transistor,
wherein the second common impurity region is disposed on the upper surface of the substrate and is adjacent to one of the pair of sidewalls of the level balancing gate electrode pattern, and
wherein the first common impurity region is disposed on the upper surface of the substrate and adjacent to the other of the pair of sidewalls of the level balancing gate electrode pattern.

5. The memory device as claimed in claim 4,
wherein the first common impurity region is disposed at a boundary between the first PMOS active region and the connected active region, and
wherein the second common impurity region is disposed at a boundary between the second PMOS active region and the connected active region.

6. The memory device as claimed in claim 4,
wherein the first gate electrode pattern of the first PMOS transistor is disposed on the first PMOS active region,
wherein the first PMOS transistor further comprises:
a second impurity region as the other of the pair of source/drain regions of the first PMOS transistor,
wherein the first gate electrode pattern comprises:
a first rectangular main region having a pair of first long sidewalls extending in the first direction and a pair of first short sidewalls extending in the second direction; and
a first rectangular extended region extending in the second direction from one of the pair of first long sidewalls of the first rectangular main region,
wherein the second impurity region of the first PMOS transistor is disposed on the upper surface of the substrate and adjacent to the other of the pair of first long sidewalls of the first rectangular main region, and
wherein the first common impurity region is adjacent to one of the pair of first short sidewalls of the first rectangular main region.

7. The memory device as claimed in claim 6,
wherein the second gate electrode pattern of the second PMOS transistor is disposed on the second PMOS active region,
wherein the second PMOS transistor further comprises:
a second impurity region as the other of the pair of source/drain regions of the second PMOS transistor,
wherein the second gate electrode pattern comprises:
a second rectangular main region having a pair of second long sidewalls extending in the first direction and a pair of second short sidewalls extending in the second direction; and
a second rectangular extended region extending in the second direction from one of the pair of second long sidewalls of the second rectangular main region,
wherein the second impurity region of the second PMOS transistor is disposed on the upper surface of the substrate and adjacent to the other of the pair of second long sidewalls of the second rectangular main region,
wherein the first impurity region of the second PMOS transistor is the second common impurity region shared between the second PMOS transistor and the level balancing transistor, and
wherein the second common impurity region is adjacent to one of the pair of second short sidewalls of the second rectangular main region.

8. The memory device as claimed in claim 7,
wherein the bitline sense amplifier further comprises:
a first contact disposed on the first impurity region;
a second contact disposed on the second impurity region;
a first common contact disposed on the first common impurity region; and
a second common contact disposed on the second common impurity region.

9. The memory device as claimed in claim 7,
wherein the one of the pair of first short sidewalls of the first rectangular main region and the one of the pair of second short sidewalls of the second rectangular main region are adjacent to each other.

10. The memory device as claimed in claim 7,
wherein the active region further comprises:
a third PMOS active region connected to the first PMOS active region; and
a fourth PMOS active region connected to the second PMOS active region and the third PMOS active region,
wherein the P-type sense amplifier further comprises:
a third PMOS transistor disposed on the third PMOS active region; and
a fourth PMOS transistor disposed on the fourth PMOS active region,
wherein the third PMOS transistor comprises a third gate electrode pattern disposed on the third PMOS active region,
wherein the fourth PMOS transistor comprises a fourth gate electrode pattern disposed on the fourth PMOS active region,
wherein the third gate electrode pattern is adjacent to the other of the pair of first long sidewalls of the first rectangular main region, and
wherein the fourth gate electrode pattern is adjacent to the other of the pair of second long sidewalls of the second rectangular main region.

11. The memory device as claimed in claim 7,
wherein the active region further comprises:
a third PMOS active region connected to the first PMOS active region; and
a fourth PMOS active region connected to the third PMOS active region,
wherein the P-type sense amplifier further comprises:
a third PMOS transistor disposed on the third PMOS active region; and
a fourth PMOS transistor disposed on the fourth PMOS active region,
wherein the third PMOS transistor comprises a third gate electrode pattern disposed on the third PMOS active region,
wherein the fourth PMOS transistor comprises a fourth gate electrode pattern disposed on the fourth PMOS active region,
wherein the third gate electrode pattern is adjacent to the other of the pair of first long sidewalls of the first rectangular main region, and
wherein the fourth gate electrode pattern is adjacent to the one of the pair of second long sidewalls of the second rectangular main region.

12. The memory device as claimed in claim 10,
wherein the third gate electrode pattern of the third PMOS transistor is connected to a second sensing bitline, and
wherein the fourth gate electrode pattern of the fourth PMOS transistor is connected to a second complementary sensing bitline.

13. A memory device comprising:
a bitline sense amplifier sensing a voltage difference between a bit line and a complementary bitline; and
a substrate on which a first PMOS active region, a second PMOS active region, and a connected active region connected to the first PMOS active region and the second PMOS active region are defined,
wherein the bitline sense amplifier comprises:
an N-type sense amplifier connected to the bitline and the complementary bitline;
a P-type sense amplifier connected to the N-type sense amplifier through a first sensing bitline and a first complementary sensing bitline; and
a level balancing transistor connecting the first sensing bitline and the first complementary sensing bitline based on a level balancing control signal,
wherein the P-type sense amplifier comprises:
a first PMOS transistor having a first gate electrode pattern connected to the first sensing bitline; and
a second PMOS transistor having a second gate electrode pattern connected to the first complementary sensing bitline,
wherein the level balancing transistor comprises:
a level balancing gate pattern disposed on the connected active region and comprising a pair of sidewalls spaced apart in a first direction parallel to an upper surface of the substrate and extending in a second direction parallel to the upper surface of the substrate and intersecting the first direction;
a first common impurity region disposed on the upper surface of the substrate as one of a pair of source/drain regions of the level balancing transistor and adjacent to one of the pair of sidewalls of the level balancing gate pattern; and
a second common impurity region disposed on the upper surface of the substrate as the other of the pair of source/drain regions of the level balancing transistor and adjacent to the other of the pair of sidewalls of the level balancing gate pattern,
wherein the level balancing transistor shares the first common impurity region with the first PMOS transistor and shares the second common impurity region with the second PMOS transistor.

14. The memory device as claimed in claim 13,
wherein the level balancing transistor, when viewed in a plan view, is disposed in a space between the first PMOS transistor and the second PMOS transistor.

15. The memory device as claimed in claim 13,
wherein the first PMOS transistor is disposed on the first PMOS active region,
wherein the second PMOS transistor is disposed on the second PMOS active region,
wherein the connected active region, when viewed in a plan view, is disposed between the first PMOS active region and the second PMOS active region,
wherein the first common impurity region is disposed at a boundary between the first PMOS active region and the connected active region, and
wherein the second common impurity region is disposed at a boundary between the second PMOS active region and the connected active region.

16. The memory device as claimed in claim 15,
wherein the first gate electrode pattern of the first PMOS transistor is disposed on the first PMOS active region,
wherein the first PMOS transistor further comprises:
a first impurity region as one of a pair of source/drain regions of the first PMOS transistor; and
the first common impurity region as the other of the pair of source/drain regions of the first PMOS transistor,
wherein the first gate electrode pattern of the first PMOS transistor comprise:
a first rectangular main region having a pair of first long sidewalls extending in the first direction and a pair of first short sidewalls extending in the second direction; and
a first rectangular extended region extending in the second direction from one of the pair of first long sidewalls of the first rectangular main region,
wherein the first impurity region of the first PMOS transistor is disposed on the upper surface of the substrate and adjacent to the other of the pair of first long sidewalls of the first rectangular main region, and
wherein the first common impurity region is adjacent to one of the pair of first short sidewalls of the first rectangular main region.

17. The memory device as claimed in claim 16,
wherein the second gate electrode pattern of the second PMOS transistor is disposed on the second PMOS active region,
wherein the second PMOS transistor further comprises:
a second impurity region disposed on the upper surface of the substrate as one of a pair of source/drain regions of the second PMOS transistor;
the second common impurity region as the other of the pair of source/drain regions, wherein the second gate electrode pattern of the second PMOS transistor comprises:
a second rectangular main region having a pair of second long sidewalls extending in the first direction and a pair of second short sidewalls extending in the second direction; and
a second rectangular extended region extending in the second direction from one of the pair of second long sidewalls of the second rectangular main region,
wherein the second impurity region of the second PMOS transistor is adjacent to the other of the pair of second long sidewalls of the second rectangular main region, and
wherein the second common impurity region is disposed adjacent to one of the pair of second short sidewalls of the second rectangular main region.

18. The memory device as claimed in claim 17,
wherein the one of the pair of first short sidewalls of the first rectangular main region and the one of the pair of second short sidewalls of the second rectangular main region are adjacent to each other.

19. The memory device as claimed in claim 17,
wherein the P-type sense amplifier further comprises:
a third PMOS transistor disposed on a third PMOS active region and having a third gate electrode pattern connected to a second sensing bitline; and
a fourth PMOS transistor disposed on a fourth PMOS active region and having a fourth gate electrode pattern connected to a second complementary sensing bitline,
wherein the third PMOS active region is connected to the first PMOS active region, and the fourth PMOS active region is connected to the third PMOS active region,
wherein the third gate electrode pattern of the third PMOS transistor is disposed on the third PMOS active region,
wherein the fourth gate electrode pattern of the fourth PMOS transistor is disposed on the fourth PMOS active region,
wherein the third gate electrode pattern is adjacent to the other of the pair of first long sidewalls of the first rectangular main region, and
wherein the fourth gate electrode pattern is adjacent to the one of the pair of second long sidewalls of the second rectangular main region.

20. (canceled)

21. A memory device comprising:
a bitline sense amplifier sensing a voltage difference of a bitline and a complementary bitline,
wherein the bitline sense amplifier comprises:
an N-type sense amplifier connected to the bitline and the complementary bitline;
a P-type sense amplifier including a first P-type metal-oxide-semiconductor (PMOS) transistor and a second PMOS transistor and connected to the N-type sense amplifier through a first sensing bitline and a first complementary sensing bitline; and
a level balancing transistor including a first impurity region and a second impurity region as a pair of source/drain regions of the level balancing transistor and connecting the first sensing bitline and the first complementary sensing bitline based on a level balancing control signal,
wherein the first impurity region of the level balancing transistor is shared with the first PMOS transistor, and
wherein the second impurity region of the level balancing transistor is shared with the second PMOS transistor.
